(19) United States
(12) Patent Application Publication
(10) Pub. No.: US 2007/0001886 A1
(43) Pub. Date: Jan. 4, 2007

(54) Integrated circuit device and electronic instrument

(75) Inventors: Satoru Ito, Suwa-shi (JP); Masahiko Moriguchi, Suwa-shi (JP); Kazuhiro Maekawa, Chino-shi (JP); Noboru Itomi, Nirasaki-shi (JP); Satoru Kodaira, Chino-shi (JP); Junichi Karasawa, Tatsuno-machi (JP); Takashi Kumagai, Chino-shi (JP); Hisanobu Ishiyama, Chino-shi (JP); Takashi Fujise, Shiojiri-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/477,646

(22) Filed: Jun. 30, 2006

(30) Foreign Application Priority Data
Jun. 30, 2005 (JP) 2005-192479
Feb. 10, 2006 (JP) 2006-034495

(51) Int. Cl. H03M 1/66

(52) U.S. Cl. 341/144

(57) ABSTRACT

An integrated circuit device includes a driver macrocell in which a plurality of circuit blocks are integrated into a macrocell. The driver macrocell includes a data driver block DB for driving data lines, a memory block MB which stores image data, and a pad block PDB in which pads for electrically connecting output lines of the data driver block DB with the data lines are disposed. The data driver block DB and the memory block MB are disposed along a direction D1, and the pad block PDB is disposed on the D2 side of the data driver block DB and the memory block MB.

Japanese Patent Application No. 2005-192479, filed on Jun. 30, 2005, and Japanese Patent Application No. 2006-34495, filed on Feb. 10, 2006, are hereby incorporated by reference in their entirety.

### BACKGROUND OF THE INVENTION

The present invention relates to an integrated circuit device and an electronic instrument.

A display driver (LCD driver) is an example of an integrated circuit device which drives a display panel such as a liquid crystal panel (JP-A-2001-222249). A reduction in the chip size is required for the display driver in order to reduce cost.

However, the size of the display panel incorporated in a portable telephone or the like is almost constant. Therefore, if the chip size is reduced by merely shrinking the integrated circuit device as the display driver by using a microfabrication technology, it becomes difficult to mount the integrated circuit device.

### SUMMARY

A first aspect of the invention relates to an integrated circuit device comprising at least one driver macrocell in which a plurality of circuit blocks are integrated into a macrocell, the driver macrocell including:

a data driver block for driving data lines;

a memory block which stores image data used by the data driver block for driving the data lines;

and a pad block in which pads for electrically connecting output lines of the data driver block with the data lines are disposed,

the data driver block and the memory block being disposed along a first direction, and the pad block being disposed on a second direction side of the data driver block and the memory block, the second direction being perpendicular to the first direction.

A second aspect of the invention relates to an integrated circuit device comprising at least one data driver block for driving data lines, the data driver block including:

a plurality of subpixel driver cells, each of the subpixel driver cells outputting a data signal corresponding to image data of one subpixel,

when a direction along a long side of the subpixel driver cell is a first direction and a direction perpendicular to the first direction is a second direction, the subpixel driver cells being disposed in the data driver block along the first direction and the second direction,

pads for electrically connecting output lines of the data driver block with the data lines being disposed on the second direction side of the data driver block.

A third aspect of the invention relates to an electronic instrument comprising:

the above integrated circuit device; and

a display panel driven by the integrated circuit device.

### BRIEF DESCRIPTION OF THE SEVERAL VIEWS OF THE DRAWING

FIGS. 1A, 1B, and 1C are illustrative of a comparative example of one embodiment of the invention.

FIGS. 2A and 2B are illustrative of mounting of an integrated circuit device.

FIG. 3 is a configuration example of an integrated circuit device according to one embodiment of the invention.

FIG. 4 is an example of various types of display drivers and circuit blocks provided in the display drivers.

FIGS. 5A and 5B are planar layout examples of the integrated circuit device according to one embodiment of the invention.

FIGS. 6A and 6B are examples of cross-sectional views of the integrated circuit device.

FIG. 7 is a circuit configuration example of the integrated circuit device.

FIGS. 8A, 8B, and 8C are illustrative of configuration examples of a data driver and a scan driver.

FIGS. 9A and 9B are configuration examples of a power supply circuit and a grayscale voltage generation circuit.

FIGS. 10A, 10B, and 10C are configuration examples of a D/A conversion circuit and an output circuit.

FIGS. 11A and 11B are views illustrative of a macrocell integration method according to one embodiment of the invention.

FIGS. 12A and 12B are other views illustrative of the macrocell integration method according to one embodiment of the invention.

FIG. 13 is a configuration example of a repeater block.

FIGS. 14A and 14B are views illustrative of a memory/data driver block division method.

FIG. 15 is a view illustrative of a method of reading image data a plurality of times in one horizontal scan period.

FIG. 16 is an arrangement example of data drivers and driver cells.

FIG. 17 is an arrangement example of subpixel driver cells.

FIG. 18 is an arrangement example of sense amplifiers and memory cells.

FIG. 19 is a configuration example of the subpixel driver cell.

FIG. 20 is a configuration example of a D/A converter.

FIGS. 21A, 21B, and 21C are views of a truth table of a sub decoder of the D/A converter and a layout of the D/A converter.

FIG. 22 is a view illustrative of a pad wiring method.

FIGS. 23A and 23B illustrate a configuration example of an electronic instrument.

### DETAILED DESCRIPTION OF THE EMBODIMENT

The invention may provide an integrated circuit device which can reduce the circuit area, and an electronic instrument including the same.

One embodiment of the invention relates to an integrated circuit device comprising at least one driver macrocell in which a plurality of circuit blocks are integrated into a macrocell, the driver macrocell including:

a data driver block for driving data lines, a memory block which stores image data used by the data driver block for driving the data lines;

and a pad block in which pads for electrically connecting output lines of the data driver block with the data lines are disposed,

the data driver block and the memory block being disposed along a first direction, and the pad block being disposed on the second direction side of the data driver block and the memory block, the second direction being perpendicular to the first direction.

According to this embodiment, the data driver block, the memory block, and the pad block are integrated into a macrocell to form a driver macrocell. In the driver macrocell, the data driver block and the memory block are disposed along the first direction, and the pad block is disposed on the second direction side of the data driver block and the memory block. By integrating the data driver block, the pad block, and the like into a macrocell, a completed macrocell formed by routing the output lines of the data driver block to the pads by a manual layout can be used as the driver macrocell, for example. Therefore, the output line wiring region can be reduced, whereby the area of the integrated circuit device can be reduced. Moreover, since the region on the second direction side of the memory block can be utilized as the pad arrangement region in addition to the region on the second direction side of the data driver block, the pads can be efficiently disposed in the pad block, whereby the layout efficiency can be improved. Since integration into a macrocell makes it unnecessary to create an individual pad block for each data driver block, the design period can be reduced.

In the integrated circuit device according to this embodiment, when a width of the data driver block in the first direction is WDB, a width of the memory block in the first direction is WMB, and a width of the pad block in the first direction is WPB, “WDB+WMB≦WPB” may be satisfied.

The pads can be efficiently disposed in the pad block by satisfying the above relationship, whereby the area of the integrated circuit device can be reduced.

In the integrated circuit device according to this embodiment, when a width of the data driver block in the first direction is WDB, a width of the memory block in the first direction is WMB, a width of an additional circuit block included in the driver macrocell in the first direction is WAB when the driver macrocell includes the additional circuit, a pad pitch of the pads in the pad block in the first direction is PP, and a number of the pads is NP, “(NP−1)×PP<WDB+WMB+WAB<(NP+1)×PP” may be satisfied.

The pads can be disposed at a uniform pad pitch by satisfying the above relationship without creating an unnecessary space.

In the integrated circuit device according to this embodiment, “WDB+WMB+WAB≦NP×PP” may be satisfied.

In the integrated circuit device according to this embodiment, the additional circuit block may be a repeater block including a buffer which buffers at least a write data signal supplied to the memory block and outputs the buffered signal to the memory block.

The rising or falling waveform of the write data signal supplied to the memory block can be prevented from becoming round by providing such a repeater block as the additional circuit block, whereby data can be properly written into the memory block.

The integrated circuit device according to this embodiment may comprise a plurality of the driver macrocells, wherein the driver macrocells may be disposed along the first direction.

This allows the pad blocks, the data driver blocks, and the memory blocks to be disposed along the first direction by merely disposing the driver macrocells along the first direction, whereby an efficient layout of the integrated circuit device can be achieved. Moreover, integration into a macrocell makes it unnecessary to create an individual pad block for each data driver block, whereby the design period can be reduced.

In the integrated circuit device according to this embodiment, the data driver block may include a plurality of subpixel driver cells, each of the subpixel driver cells outputting a data signal corresponding to image data of one subpixel, and the subpixel driver cells may be disposed in the data driver block along the first direction and the second direction.

A layout can be flexibly designed corresponding to the specification of the data driver by disposing the subpixel driver cells in a matrix.

Another embodiment of the invention relates to an integrated circuit device comprising at least one data driver block for driving data lines, the data driver block including:

a plurality of subpixel driver cells, each of the subpixel driver cells outputting a data signal corresponding to image data of one subpixel,

when a direction along a long side of the subpixel driver cell is a first direction and a direction perpendicular to the first direction is a second direction, the subpixel driver cells being disposed in the data driver block along the first direction and the second direction,

pads for electrically connecting output lines of the data driver block with the data lines being disposed on the second direction side of the data driver block.

According to this embodiment, the subpixel driver cells are disposed along the first direction (long side direction) and the second direction perpendicular to the first direction. The pads for electrically connecting the output lines of the data driver block (subpixel driver cells) with the data lines are disposed on the second direction side of the matrix-arranged subpixel driver cells. This allows the subpixel driver cells to be stacked along the first direction (long side direction), whereby the width of the data driver block can be reduced in the second direction which is the short side direction of the subpixel driver cells. Moreover, the pads can be disposed by effectively utilizing the space on the second direction side of the matrix-arranged subpixel driver cells. This reduces the area of the integrated circuit device.

In the integrated circuit device according to this embodiment, each of the subpixel driver cells may include: a first circuit region in which a circuit which operates using a power supply at a first voltage level is disposed; and a second circuit region in which a circuit which operates using a power supply at a second voltage level higher than the first voltage level is disposed; and the subpixel driver cells may be disposed so that the second circuit regions or the first circuit regions of the subpixel driver cells are adjacent to each other along the first direction.

This allows the width of the integrated circuit device in the first direction to be reduced in comparison with a method of disposing the subpixel driver cells so that the first circuit region is adjacent to the second circuit region, whereby the area of the integrated circuit device can be reduced.

In the integrated circuit device according to this embodiment, a latch circuit which latches the image data may be disposed in the first circuit region; and a D/A converter which performs D/A conversion of the image data using a grayscale voltage may be disposed in the second circuit region.

The integrated circuit device according to this embodiment may comprise at least one memory block which stores the image data, wherein the memory block may be disposed adjacent to the first circuit region of the subpixel driver cell.

This allows the memory block which operates using a power supply at the first voltage level and the first circuit region of the subpixel driver cell to be adjacently disposed, whereby the layout efficiency can be improved.

In the integrated circuit device according to this embodiment, the subpixel driver cell may include a D/A converter which performs D/A conversion of the image data using a grayscale voltage; wherein a grayscale voltage supply line for supplying the grayscale voltage to the D/A converter may be provided along the second direction across the subpixel driver cells.

This allows the grayscale voltage to be efficiently supplied to the D/A converters of the subpixel driver cells disposed along the second direction from the grayscale voltage supply line provided along the second direction, whereby the layout efficiency can be improved.

In the integrated circuit device according to this embodiment, the grayscale voltage supply line may be provided in an arrangement region of the D/A converter.

When the D/A converter includes a grayscale voltage selector or the like, it is preferable to provide the grayscale voltage supply line in the arrangement region of the grayscale voltage selector.

In the integrated circuit device according to this embodiment, an N-type transistor region and a P-type transistor region may be disposed along the second direction in an arrangement of the D/A converter of the subpixel driver cell; and an N-type transistor region and a P-type transistor region may be disposed along the first direction in an arrangement region of a circuit of the subpixel driver cell other than the D/A converter.

This allows the grayscale voltage supply line to be connected in common with an N-type transistor in the N-type transistor region and a P-type transistor in the P-type transistor region disposed along the second direction, whereby the layout efficiency can be improved. On the other hand, an efficient layout along the signal flow may be achieved by disposing an N-type transistor region and a P-type transistor region of a circuit other than the D/A converter along the first direction.

A further embodiment of the invention relates to an electronic instrument comprising:

the above integrated circuit device; and

a display panel driven by the integrated circuit device.

These embodiments of the invention will be described in detail below. Note that the embodiments described below do not in any way limit the scope of the invention laid out in the claims herein. In addition, not all of the elements of the embodiments described below should be taken as essential requirements of the invention.

### 1. COMPARATIVE EXAMPLE

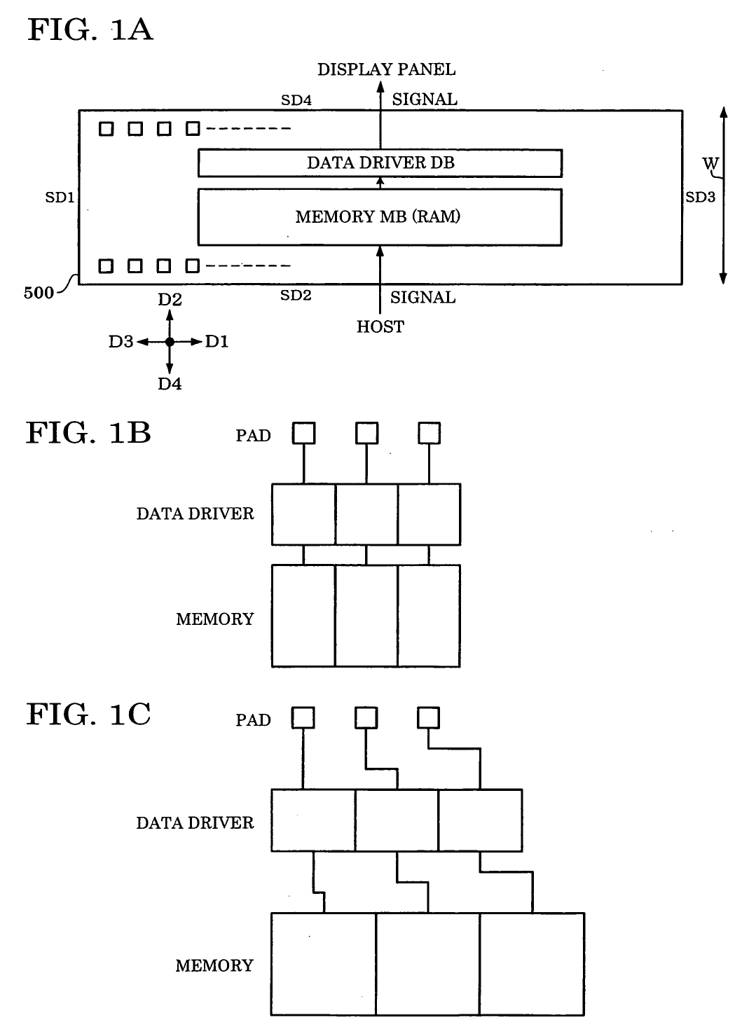

FIG. 1A shows an integrated circuit device 500 which is a comparative example of one embodiment of the invention. The integrated circuit device 500 shown in FIG. 1A includes a memory block MB (display data RAM) and a data driver block DB. The memory block MB and the data driver block DB are disposed along a direction D2. The memory block MB and the data driver block DB are ultra-flat blocks of which the length along a direction D1 is greater than the width in the direction D2.

Image data supplied from a host is written into the memory block MB. The data driver block DB converts the digital image data written into the memory block MB into an analog data voltage, and drives data lines of a display panel. In FIG. 1A, the image data signal flows in the direction D2. Therefore, in the comparative example shown in FIG. 1A, the memory block MB and the data driver block DB are disposed along the direction D2 corresponding to the signal flow. This reduces the path between the input and the output so that a signal delay can be optimized, whereby an efficient signal transmission can be achieved.

However, the comparative example shown in FIG. 1A has the following problems.

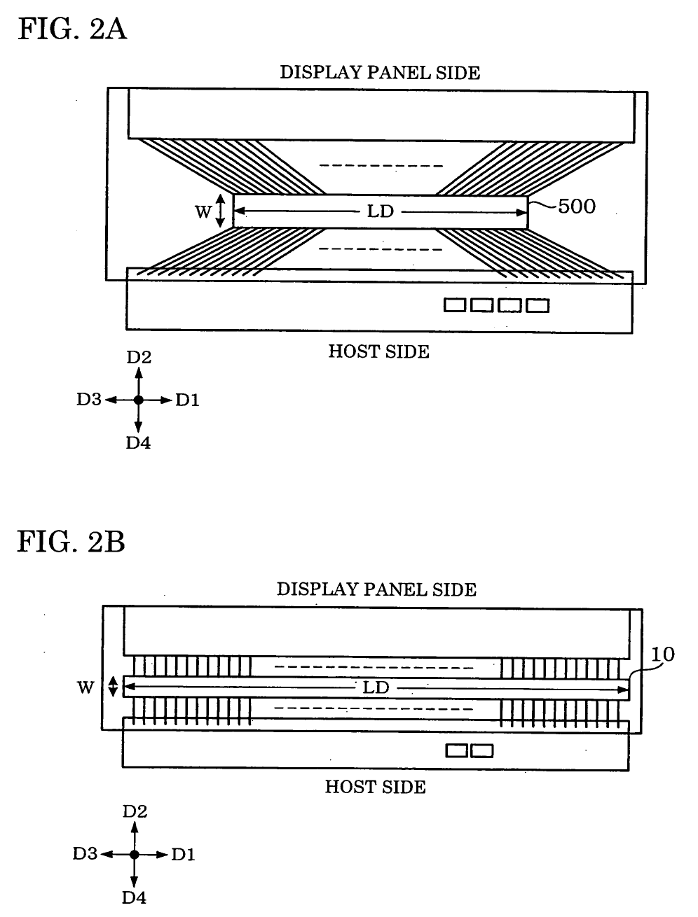

First, a reduction in the chip size is required for an integrated circuit device such as a display driver in order to reduce cost. However, if the chip size is reduced by merely shrinking the integrated circuit device 500 by using a microfabrication technology, the size of the integrated circuit device 500 is reduced not only in the short side direction but also in the long side direction. Therefore, it becomes difficult to mount the integrated circuit device 500 as shown in FIG. 2A. Specifically, it is desirable that the output pitch be 22 μm or more, for example. However, the output pitch is reduced to 17 μm by merely shrinking the integrated circuit device 500 as shown in FIG. 2A, for example, whereby it becomes difficult to mount the integrated circuit device 500 due to the narrow pitch. Moreover, the number of glass substrates obtained is decreased due to an increase in the glass frame of the display panel, whereby cost is increased.

Second, the configurations of the memory and the data driver of the display driver are changed corresponding to the type of display panel (amorphous TFT or low-temperature polysilicon TFT), the number of pixels (QCIF, QVGA, or VGA), the specification of the product, and the like. Therefore, in the comparative example shown in FIG. 1A, even if the pad pitch, the cell pitch of the memory, and the cell pitch of the data driver coincide in one product as shown in FIG. 1B, the pitches do not coincide as shown in FIG. 1C when the configurations of the memory and the data driver are changed. If the pitches do not coincide as shown in FIG. 1C, an unnecessary interconnect region for absorbing the pitch difference must be formed between the circuit blocks. In particular, in the comparative example shown in FIG. 1A in which the block is made flat in the direction D1, the area of an unnecessary interconnect region for absorbing the pitch difference is increased. As a result, the width W of the integrated circuit device 500 in the direction D2 is increased, whereby cost is increased due to an increase in the chip area.

If the layout of the memory and the data driver is changed so that the pad pitch coincides with the cell pitch in order to avoid such a problem, the development period is increased, whereby cost is increased. Specifically, since the circuit configuration and the layout of each circuit block are individually designed and the pitch is adjusted thereafter in the comparative example shown in FIG. 1A, unnecessary area is provided or the design becomes inefficient.

### 2. CONFIGURATION OF INTEGRATED CIRCUIT DEVICE

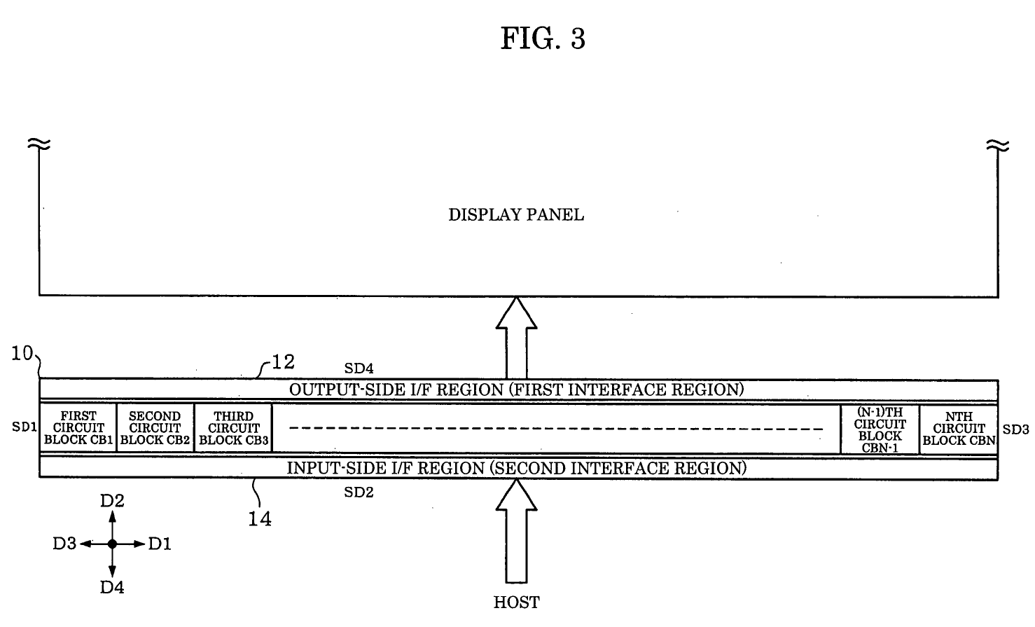

FIG. 3 shows a configuration example of an integrated circuit device 10 according to one embodiment of the invention which can solve the above-described problems. In this embodiment, the direction from a first side SD1 (short side) of the integrated circuit device 10 toward a third side SD3 opposite to the first side SD1 is defined as a first direction D1, and the direction opposite to the first direction D1 is defined as a third direction D3. The direction from a second side SD2 (long side) of the integrated circuit device 10 toward a fourth side SD4 opposite to the second side SD2 is defined as a second direction D2, and the direction opposite to the second direction D2 is defined as a fourth direction D4. In FIG. 3, the left side of the integrated circuit device 10 is the first side SD1, and the right side is the third side SD3. However, the left side may be the third side SD3, and the right side may be the first side SD1.

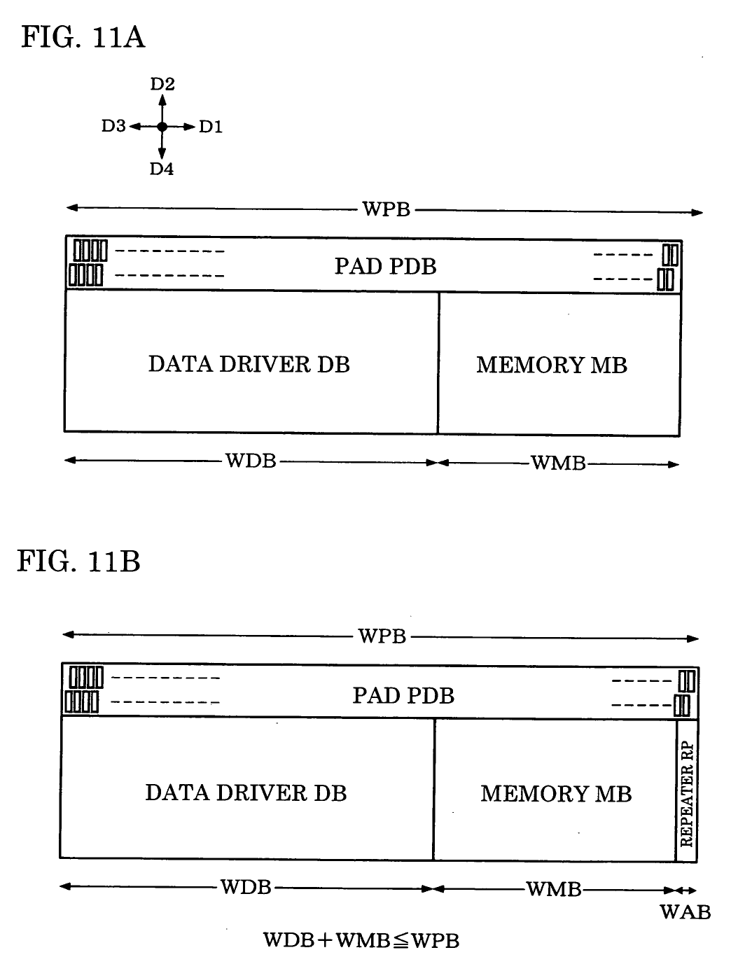

As shown in FIG. 3, the integrated circuit device 10 according to this embodiment includes first to Nth circuit blocks CB1 to CBN (N is an integer larger than one) disposed along the direction D1. Specifically, while the circuit blocks are arranged in the direction D2 in the comparative example shown in FIG. 11A, the circuit blocks CB1 to CBN are arranged in the direction D1 in this embodiment. Each circuit block is a relatively square block differing from the ultra-flat block as in the comparative example shown in FIG. 1A.

The integrated circuit device 10 includes an output-side I/F region 12 (first interface region in a broad sense) provided along the side SD4 and on the D2 side of the first to Nth circuit blocks CB1 to CBN. The integrated circuit device 10 includes an input-side I/F region 14 (second interface region in a broad sense) provided along the side SD2 and on the D4 side of the first to Nth circuit blocks CB1 to CBN. In more detail, the output-side I/F region 12 (first I/O region) is disposed on the D2 side of the circuit blocks CB1 to CBN without other circuit blocks interposed therebetween, for example. The input-side I/F region 14 (second I/O region) is disposed on the D4 side of the circuit blocks CB1 to CBN without other circuit blocks interposed therebetween, for example. Specifically, only one circuit block (data driver block) exists in the direction D2 at least in the area in which the data driver block exists. When the integrated circuit device 10 is used as an intellectual property (IP) core and incorporated in another integrated circuit device, the integrated circuit device 10 may be configured to exclude at least one of the I/F regions 12 and 14.

The output-side (display panel side) I/F region 12 is a region which serves as an interface between the integrated circuit device 10 and the display panel, and includes pads and various elements such as output transistors and protective elements connected with the pads. In more detail, the output-side I/F region 12 includes output transistors for outputting data signals to data lines and scan signals to scan lines, for example. When the display panel is a touch panel, the output-side I/F region 12 may include input transistors.

The input-side I/F region 14 is a region which serves as an interface between the integrated circuit device 10 and a host (MPU, image processing controller, or baseband engine), and may include pads and various elements connected with the pads, such as input (input-output) transistors, output transistors, and protective elements. In more detail, the input-side I/F region 14 includes input transistors for inputting signals (digital signals) from the host, output transistors for outputting signals to the host, and the like.

An output-side or input-side I/F region may be provided along the short side SD1 or SD3. Bumps which serve as external connection terminals may be provided in the I/F (interface) regions 12 and 14, or may be provided in other regions (first to Nth circuit blocks CB1 to CBN). When providing the bumps in the region other than the I/F regions 12 and 14, the bumps are formed by using a small bump technology (e.g. bump technology using resin core) other than a gold bump technology.

The first to Nth circuit blocks CB1 to CBN may include at least two (or three) different circuit blocks (circuit blocks having different functions). Taking an example in which the integrated circuit device 10 is a display driver, the circuit blocks CB1 to CBN may include at least two of a data driver block, a memory block, a scan driver block, a logic circuit block, a grayscale voltage generation circuit block, and a power supply circuit block. In more detail, the circuit blocks CB1 to CBN may include at least a data driver block and a logic circuit block, and may further include a grayscale voltage generation circuit block. When the integrated circuit device 10 includes a built-in memory, the circuit blocks CB1 to CBN may further include a memory block.

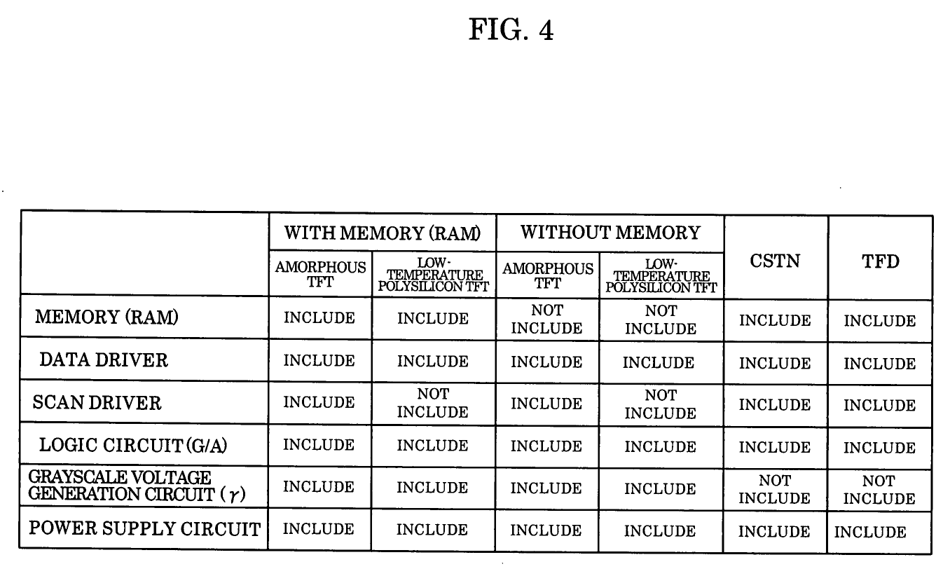

FIG. 4 shows an example of various types of display drivers and circuit blocks provided in the display drivers. In an amorphous thin film transistor (TFT) panel display driver including a built-in memory (RAM), the circuit blocks CB1 to CBN include a memory block, a data driver (source driver) block, a scan driver (gate driver) block, a logic circuit (gate array circuit) block, a grayscale voltage generation circuit (γ-correction circuit) block, and a power supply circuit block. In a low-temperature polysilicon (LTPS) TFT panel display driver including a built-in memory, since the scan driver can be formed on a glass substrate, the scan driver block may be omitted. The memory block may be omitted in an amorphous TFT panel display driver which does not include a memory, and the memory block and the scan driver block may be omitted in a low-temperature polysilicon TFT panel display driver which does not include a memory. In a color super twisted nematic (CSTN) panel display driver and a thin film diode (TFD) panel display driver, the grayscale voltage generation circuit block may be omitted.

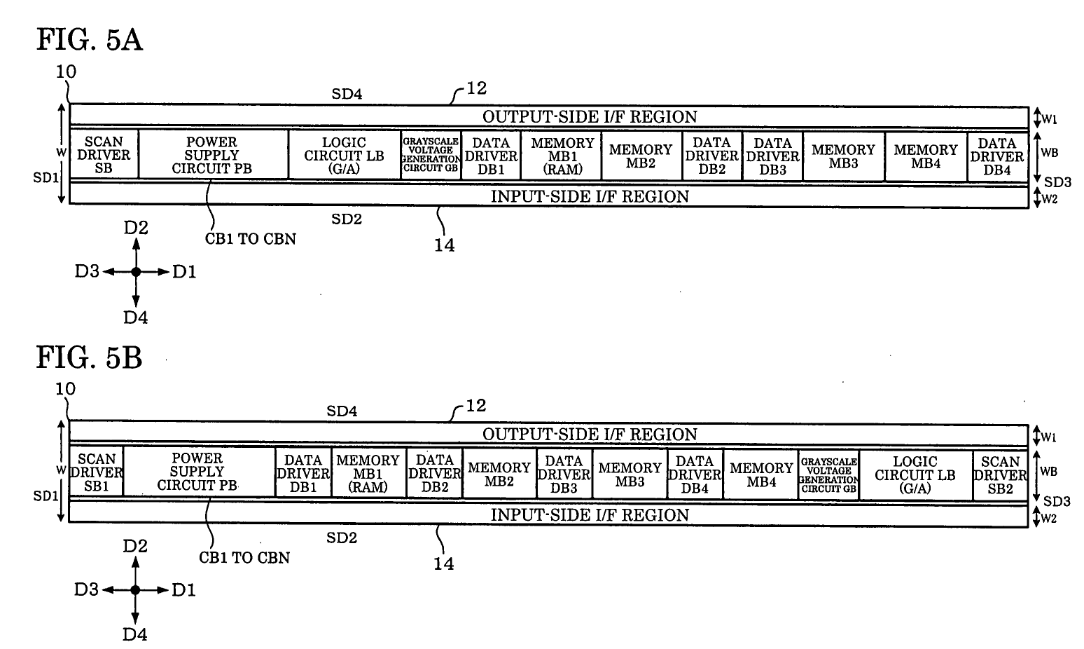

FIGS. 5A and 5B show examples of a planar layout of the integrated circuit device 10 as the display driver according to this embodiment. FIGS. 5A and 5B are examples of an amorphous TFT panel display driver including a built-in memory. FIG. 5A shows a QCIF and 32-grayscale display driver, and FIG. 5B shows a QVGA and 64-grayscale display driver.

In FIGS. 5A and 5B, the first to Nth circuit blocks CB1 to CBN include first to fourth memory blocks MB1 to MB4 (first to Ith memory blocks in a broad sense; I is an integer larger than one). The first to Nth circuit blocks CB1 to CBN include first to fourth data driver blocks DB1 to DB4 (first to Ith data driver blocks in a broad sense) respectively disposed adjacent to the first to fourth memory blocks MB1 to MB4 along the direction D1. In more detail, the memory block MB1 and the data driver block DB1 are disposed adjacent to each other along the direction D1, and the memory block MB2 and the data driver block DB2 are disposed adjacent to each other along the direction D1. The memory block MB1 adjacent to the data driver block DB1 stores image data (display data) used by the data driver block DB1 to drive the data line, and the memory block MB2 adjacent to the data driver block DB2 stores image data used by the data driver block DB2 to drive the data line.

In FIG. 5A, the data driver block DB1 (Jth data driver block in a broad sense; 1≦J<I) of the data driver blocks DB1 to DB4 is disposed adjacently on the D3 side of the memory block MB1 (Jth memory block in a broad sense) of the memory blocks MB1 to MB4. The memory block MB2 ((J+1)th memory block in a broad sense) is disposed adjacently on the D1 side of the memory block MB1. The data driver block DB2 ((J+1)th data driver block in a broad sense) is disposed adjacently on the D1 side of the memory block MB2. The arrangement of the memory blocks MB3 and MB4 and the data driver blocks DB3 and DB4 is the same as described above. In FIG. 5A, the memory block MB1 and the data driver block DB1 and the memory block MB2 and the data driver block DB2 are disposed line-symmetrical with respect to the borderline between the memory blocks MB1 and MB2, and the memory block MB3 and the data driver block DB3 and the memory block MB4 and the data driver block DB4 are disposed line-symmetrical with respect to the borderline between the memory blocks MB3 and MB4. In FIG. 5A, the data driver blocks DB2 and DB3 are disposed adjacent to each other. However, another circuit block may be disposed between the data driver blocks DB2 and DB3.

In FIG. 5B, the data driver block DB1 (Jth data driver block) of the data driver blocks DB1 to DB4 is disposed adjacently on the D3 side of the memory block MB1 (Jth memory block) of the memory blocks MB1 to MB4. The data driver block DB2 ((J+1)th data driver block) is disposed on the D1 side of the memory block MB1. The memory block MB2 ((J+1)th memory block) is disposed on the D1 side of the data driver block DB2. The data driver block DB3, the memory block MB3, the data driver block DB4, and the memory block MB4 are disposed in the same manner as described above. In FIG. 5B, the memory block MB1 and the data driver block DB2, the memory block MB2 and the data driver block DB3, and the memory block MB3 and the data driver block DB4 are respectively disposed adjacent to each other. However, another circuit block may be disposed between these blocks.

The layout arrangement shown in FIG. 5A has an advantage in that a column address decoder can be used in common between the memory blocks MB1 and MB2 or the memory blocks MB3 and MB4 (between the Jth and (J+1)th memory blocks). The layout arrangement shown in FIG. 5B has an advantage in that the interconnect pitch of the data signal output lines from the data driver blocks DB1 to DB4 to the output-side I/F region 12 can be equalized so that the interconnect efficiency can be increased.

The layout arrangement of the integrated circuit device 10 according to this embodiment is not limited to those shown in FIGS. 5A and 5B. For example, the number of memory blocks and data driver blocks may be set at 2, 3, or 5 or more, or the memory block and the data driver block may not be divided into blocks. A modification in which the memory block is not disposed adjacent to the data driver block is also possible. A configuration is also possible in which the memory block, the scan driver block, the power supply circuit block, or the grayscale voltage generation circuit block is not provided. A circuit block having a width significantly small in the direction D2 (narrow circuit block having a width less than the width WB) may be provided between the circuit blocks CB1 to CBN and the output-side I/F region 12 or the input-side I/F region 14. The circuit blocks CB1 to CBN may include a circuit block in which different circuit blocks are arranged in stages in the direction D2. For example, the scan driver circuit and the power supply circuit may be formed in one circuit block.

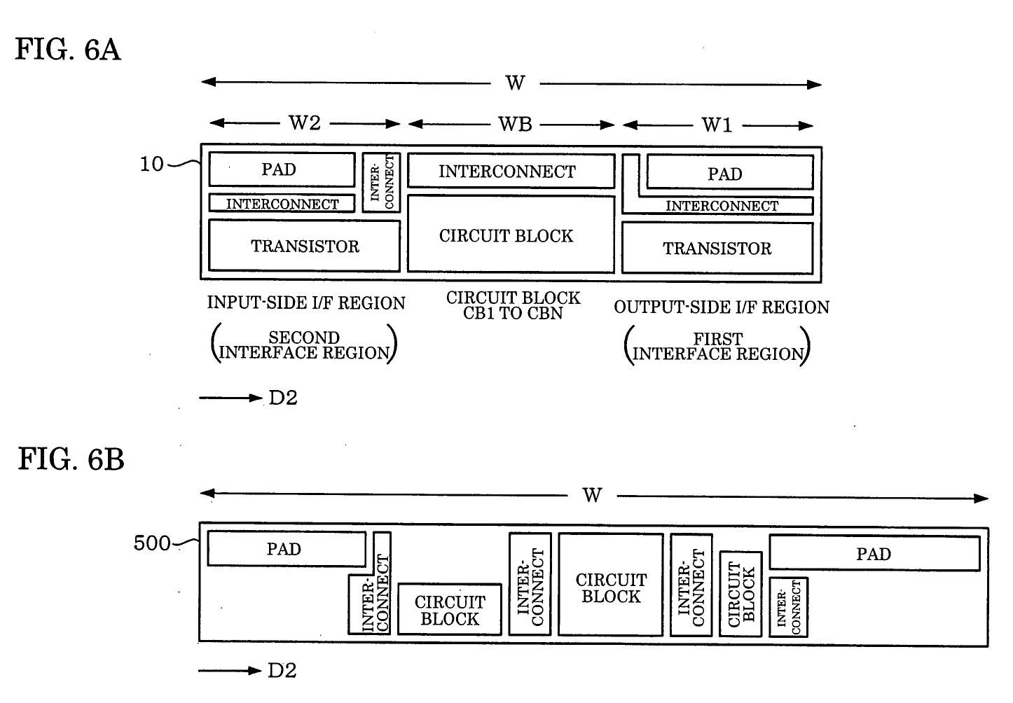

FIG. 6A shows an example of a cross-sectional view of the integrated circuit device 10 according to this embodiment along the direction D2. W1, WB, and W2 respectively indicate the widths of the output-side I/F region 12, the circuit blocks CB1 to CBN, and the input-side I/F region 14 in the direction D2. W indicates the width of the integrated circuit device 10 in the direction D2.

In this embodiment, as shown in FIG. 6A, a configuration may be employed in which a circuit block is not provided between the circuit blocks CB1 to CBN (data driver block DB) and the output-side I/F region 12 or input-side I/F region 14. Therefore, the relationship “W1+WB+W2≦W<W1+2×WB+W2” is satisfied so that a slim integrated circuit device can be realized. In more detail, the width W in the direction D2 may be set at “W<2 mm”. More specifically, the width W in the direction D2 may be set at “W<1.5 mm”. It is preferable that “W>0.9 mm” taking inspection and mounting of the chip into consideration. A length LD in the long side direction may be set at “15 mm<LD<27 mm”. A chip shape ratio SP (=LD/W) may be set at “SP>10”. More specifically, the chip shape ratio SP may be set at “SP>12”.

The widths W1, WB, and W2 shown in FIG. 6A indicate the widths of transistor formation regions (bulk regions or active regions) of the output-side I/F region 12, the circuit blocks CB1 to CBN, and the input-side I/F region 14, respectively. Specifically, output transistors, input transistors, input-output transistors, transistors of electrostatic protection elements, and the like are formed in the I/F regions 12 and 14. Transistors which form circuits are formed in the circuit blocks CB1 to CBN. The widths W1, WB, and W2 are determined based on well regions and diffusion regions by which such transistors are formed. In order to realize a slim integrated circuit device, it is preferable to form bumps (active surface bumps) on the transistors of the circuit blocks CB1 to CBN. In more detail, a resin core bump in which the core is formed of a resin and a metal layer is formed on the surface of the resin or the like is formed above the transistor (active region). These bumps (external connection terminals) are connected with the pads disposed in the I/F regions 12 and 14 through metal interconnects. The widths W1, WB, and W2 according to this embodiment are not the widths of the bump formation regions, but the widths of the transistor formation regions formed under the bumps.

The widths of the circuit blocks CB1 to CBN in the direction D2 may be identical, for example. In this case, it suffices that the widths of each of the circuit blocks be substantially identical, and the widths of each of the circuit blocks may differ in the range of several to 20 μm (several tens of microns), for example. When a circuit block with a different width exists in the circuit blocks CB1 to CBN, the width WB may be the maximum width of the circuit blocks CB1 to CBN. In this case, the maximum width may be the width of the data driver block in the direction D2, for example. In the case where the integrated circuit device includes a memory, the maximum width may be the width of the memory block in the direction D2. A vacant region having a width of about 20 to 30 μm may be provided between the circuit blocks CB1 to CBN and the I/F regions 12 and 14, for example.

In this embodiment, a pad of which the number of stages in the direction D2 is one or more may be disposed in the output-side I/F region 12. Therefore, the width W1 of the output-side I/F region 12 in the direction D2 may be set at “0.13 mm≦W1≦0.4 mm” taking the pad width (e.g. 0.1 mm) and the pad pitch into consideration. Since a pad of which the number of stages in the direction D2 is one can be disposed in the input-side I/F region 14, the width W2 of the input-side I/F region 14 may be set at is “0.1 mm≦W2≦0.2 mm”. In order to realize a slim integrated circuit device, interconnects for logic signals from the logic circuit block, grayscale voltage signals from the grayscale voltage generation circuit block, and a power supply must be formed on the circuit blocks CB1 to CBN by using global lines. The total width of these interconnects is about 0.8 to 0.9 mm, for example. Therefore, the widths WB of the circuit blocks CB1 to CBN may be set at “0.65 mm≦WB≦1.2 mm” taking the total width of these interconnects into consideration.

Since “0.65 mm≦WB≦1.2 mm” is satisfied even if W1=0.4 mm and W2=0.2 mm, WB>W1+W2 is satisfied. When the widths W1, WB, and W2 are minimum values, W1=0.13 mm, WB=0.65 mm, and W2=0.1 mm so that the width W of the integrated circuit device is about 0.88 mm. Therefore, “W=0.88 mm<2×WB=1.3 mm” is satisfied. When the widths W1, WB, and W2 are maximum values, W1=0.4 mm, WB=1.2 mm, and W2=0.2 mm so that the width W of the integrated circuit device is about 1.8 mm. Therefore, “W=1.8 mm<2×WB=2.4 mm” is satisfied. Therefore, the relational equation “W<2×WB” is satisfied so that a slim integrated circuit device is realized.

In the comparative example shown in FIG. 1A, two or more circuit blocks are disposed along the direction D2 as shown in FIG. 6B. Moreover, interconnect regions are formed between the circuit blocks and between the circuit blocks and the I/F region in the direction D2. Therefore, since the width W of the integrated circuit device 500 in the direction D2 (short side direction) is increased, a slim chip cannot be realized. Therefore, even if the chip is shrunk by using a microfabrication technology, the length LD in the direction D1 (long side direction) is decreased, as shown in FIG. 2A, so that the output pitch becomes narrow, whereby it becomes difficult to mount the integrated circuit device 500.

In this embodiment, the circuit blocks CB1 to CBN are disposed along the direction D1 as shown in FIGS. 3, 5A, and 5B. As shown in FIG. 6A, the transistor (circuit element) can be disposed under the pad (bump) (active surface bump). Moreover, the signal lines can be formed between the circuit blocks and between the circuit blocks and the I/F by using the global lines formed in the upper layer (lower layer of the pad) of the local interconnects in the circuit blocks. Therefore, since the width W of the integrated circuit device 10 in the direction D2 can be reduced while maintaining the length LD of the integrated circuit device 10 in the direction D1 as shown in FIG. 2B, a very slim chip can be realized. As a result, since the output pitch can be maintained at 22 μm or more, for example, mounting can be facilitated.

In this embodiment, since the circuit blocks CB1 to CBN are disposed along the direction D1, it is possible to easily deal with a change in the product specifications and the like. Specifically, since product of various specifications can be designed by using a common platform, the design efficiency can be increased. For example, when the number of pixels or the number of grayscales of the display panel is increased or decreased in FIGS. 5A and 5B, it is possible to deal with such a situation merely by increasing or decreasing the number of blocks of memory blocks or data driver blocks, the number of read operations of image data in one horizontal scan period, or the like. FIGS. 5A and 5B show an example of an amorphous TFT panel display driver including a memory. When developing a low-temperature polysilicon TFT panel product including a memory, it suffices to remove the scan driver block from the circuit blocks CB1 to CBN. When developing a product which does not include a memory, it suffices to remove the memory block from the circuit blocks CB1 to CBN. In this embodiment, even if the circuit block is removed corresponding to the specification, since the effect on the remaining circuit blocks is minimized, the design efficiency can be increased.

In this embodiment, the widths (heights) of the circuit blocks CB1 to CBN in the direction D2 can be uniformly adjusted to the width (height) of the data driver block or the memory block, for example. Since it is possible to deal with an increase or decrease in the number of transistors of each circuit block by increasing or decreasing the length of each circuit block in the direction D1, the design efficiency can be further increased. For example, when the number of transistors is increased or decreased in FIGS. 5A and 5B due to a change in the configuration of the grayscale voltage generation circuit block or the power supply circuit block, it is possible to deal with such a situation by increasing or decreasing the length of the grayscale voltage generation circuit block or the power supply circuit block in the direction D1.

As a second comparative example, a narrow data driver block may be disposed in the direction D1, and other circuit blocks such as the memory block may be disposed along the direction D1 on the D4 side of the data driver block, for example. However, in the second comparative example, since the data driver block having a large width lies between other circuit blocks such as the memory block and the output-side I/F region, the width W of the integrated circuit device in the direction D2 is increased, so that it is difficult to realize a slim chip. Moreover, an additional interconnect region is formed between the data driver block and the memory block, whereby the width W is further increased. Furthermore, when the configuration of the data driver block or the memory block is changed, the pitch difference described with reference to FIGS. 1B and 1C occurs, whereby the design efficiency cannot be increased.

As a third comparative example of this embodiment, only circuit blocks (e.g. data driver blocks) having the same function may be divided and arranged in the direction D1. However, since the integrated circuit device can be provided with only a single function (e.g. function of the data driver) in the third comparative example, development of various products cannot be realized. In this embodiment, the circuit blocks CB1 to CBN include circuit blocks having at least two different functions. Therefore, various integrated circuit devices corresponding to various types of display panels can be provided as shown in FIGS. 4, 5A, and 5B.

### 3. CIRCUIT CONFIGURATION

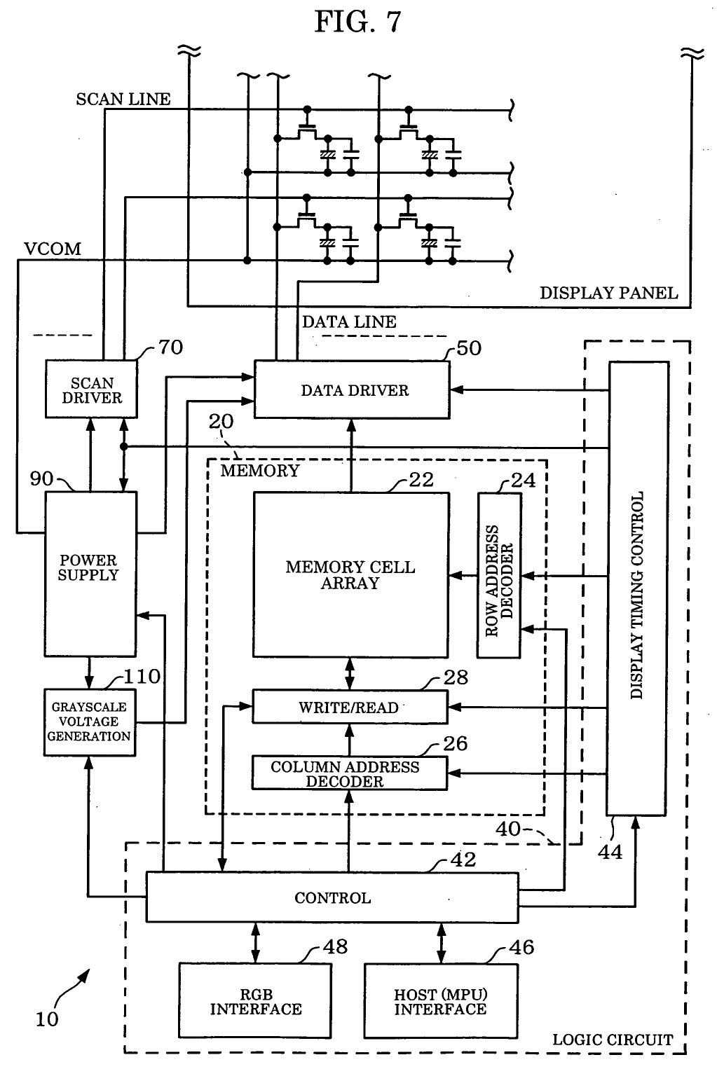

FIG. 7 shows a circuit configuration example of the integrated circuit device 10. The circuit configuration of the integrated circuit device 10 is not limited to the circuit configuration shown in FIG. 7. Various modifications and variations may be made. A memory 20 (display data RAM) stores image data. A memory cell array 22 includes a plurality of memory cells, and stores image data (display data) for at least one frame (one screen). In this case, one pixel is made up of R, G, and B subpixels (three dots), and 6-bit (k-bit) image data is stored for each subpixel, for example. A row address decoder 24 (MPU/LCD row address decoder) decodes a row address and selects a wordline of the memory cell array 22. A column address decoder 26 (MPU column address decoder) decodes a column address and selects a bitline of the memory cell array 22. A write/read circuit 28 (MPU write/read circuit) writes image data into the memory cell array 22 or reads image data from the memory cell array 22. An access region of the memory cell array 22 is defined by a rectangle having a start address and an end address as opposite vertices. Specifically, the access region is defined by the column address and the row address of the start address and the column address and the row address of the end address so that memory access is performed.

A logic circuit 40 (e.g. automatic placement and routing circuit) generates a control signal for controlling display timing, a control signal for controlling data processing timing, and the like. The logic circuit 40 may be formed by automatic placement and routing (e.g. gate array (G/A)). A control circuit 42 generates various control signals and controls the entire device. In more detail, the control circuit 42 outputs grayscale characteristic (γ-characteristic) adjustment data (γ-correction data) to a grayscale voltage generation circuit 110 and controls voltage generation of a power supply circuit 90. The control circuit 42 controls write/read processing for the memory using the row address decoder 24, the column address decoder 26, and the write/read circuit 28. A display timing control circuit 44 generates various control signals for controlling display timing, and controls reading of image data from the memory into the display panel. A host (MPU) interface circuit 46 realizes a host interface which accesses the memory by generating an internal pulse each time access by the host occurs. An RGB interface circuit 48 realizes an RGB interface which writes motion picture RGB data into the memory based on a dot clock signal. The integrated circuit device 10 may be configured to include only one of the host interface circuit 46 and the RGB interface circuit 48.

In FIG. 7, the host interface circuit 46 and the RGB interface circuit 48 access the memory 20 in pixel units. Image data designated by a line address and read in line units is supplied to a data driver 50 in line cycle at an internal display timing independent of the host interface circuit 46 and the RGB interface circuit 48.

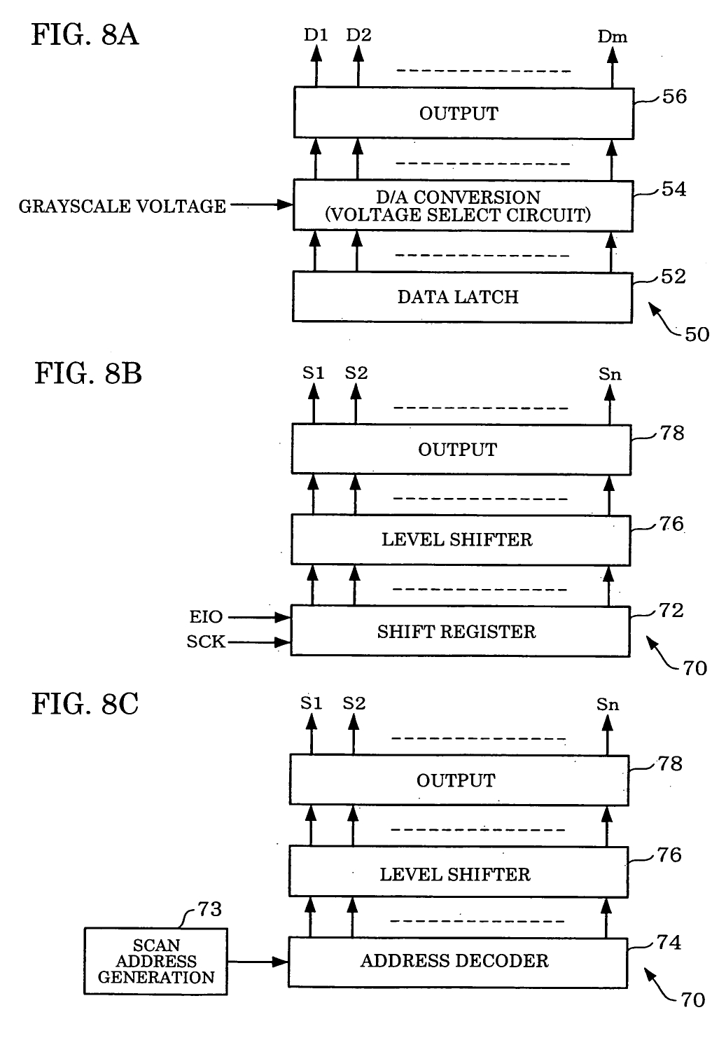

The data driver 50 is a circuit for driving a data line of the display panel. FIG. 8A shows a configuration example of the data driver 50. A data latch circuit 52 latches the digital image data from the memory 20. A D/A conversion circuit 54 (voltage select circuit) performs D/A conversion of the digital image data latched by the data latch circuit 52, and generates an analog data voltage. In more detail, the D/A conversion circuit 54 receives a plurality of (e.g. 64 stages) grayscale voltages (reference voltages) from the grayscale voltage generation circuit 110, selects a voltage corresponding to the digital image data from the grayscale voltages, and outputs the selected voltage as the data voltage. An output circuit 56 (driver circuit or buffer circuit) buffers the data voltage from the D/A conversion circuit 54, and outputs the data voltage to the data line of the display panel to drive the data line. A part of the output circuit 56 (e.g. output stage of operational amplifier) may not be included in the data driver 50 and may be disposed in another region.

A scan driver 70 is a circuit for driving a scan line of the display panel. FIG. 8B shows a configuration example of the scan driver 70. A shift register 72 includes a plurality of sequentially connected flip-flops, and sequentially shifts an enable input-output signal EIO in synchronization with a shift clock signal SCK. A level shifter 76 converts the voltage level of the signal from the shift register 72 into a high voltage level for selecting the scan line. An output circuit 78 buffers a scan voltage converted and output by the level shifter 76, and outputs the scan voltage to the scan line of the display panel to drive the scan line. The scan driver 70 may be configured as shown in FIG. 8C. In FIG. 8C, a scan address generation circuit 73 generates and outputs a scan address, and an address decoder decodes the scan address. The scan voltage is output to the scan line specified by the decode processing through the level shifter 76 and the output circuit 78.

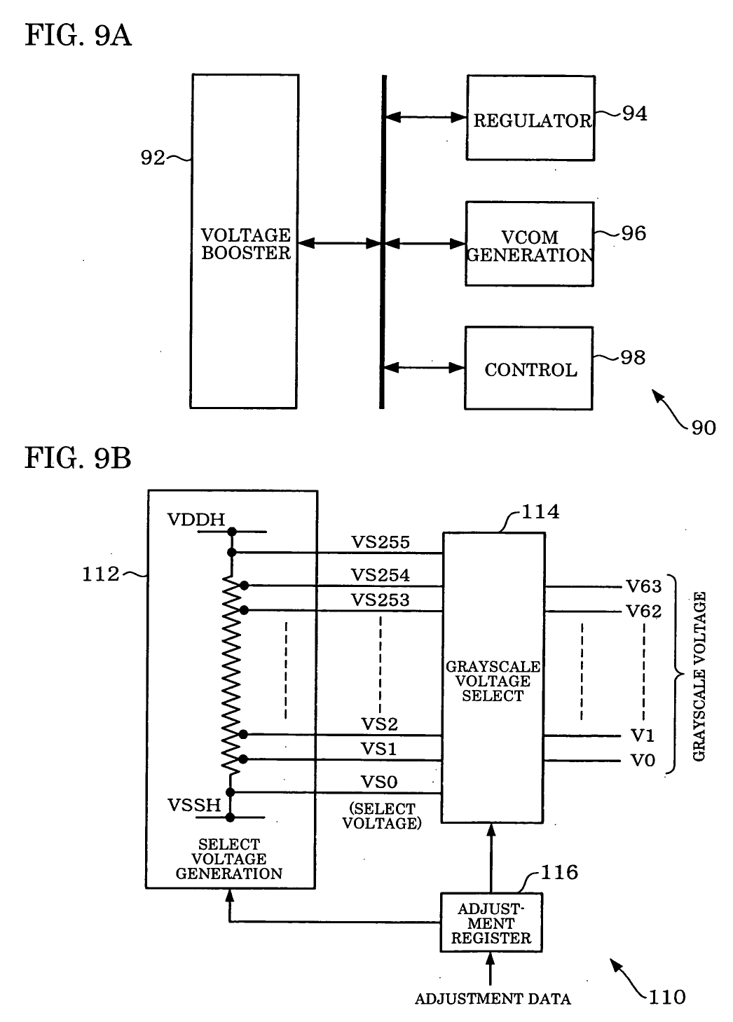

The power supply circuit 90 is a circuit which generates various power supply voltages. FIG. 9A shows a configuration example of the power supply circuit 90. A voltage booster circuit 92 is a circuit which generates a boosted voltage by boosting an input power source voltage or an internal power supply voltage by a charge-pump method using a boost capacitor and a boost transistor, and may include first to fourth voltage booster circuits and the like. A high voltage used by the scan driver 70 and the grayscale voltage generation circuit 110 can be generated by the voltage booster circuit 92. A regulator circuit 94 regulates the level of the boosted voltage generated by the voltage booster circuit 92. A VCOM generation circuit 96 generates and outputs a voltage VCOM supplied to a common electrode of the display panel. A control circuit 98 controls the power supply circuit 90, and includes various control registers and the like.

The grayscale voltage generation circuit 110 (γ-correction circuit) is a circuit which generates grayscale voltages. FIG. 9B shows a configuration example of the grayscale voltage generation circuit 110. A select voltage generation circuit 112 (voltage divider circuit) outputs select voltages VS0 to VS255 (R select voltages in a broad sense) based on high-voltage power supply voltages VDDH and VSSH generated by the power supply circuit 90. In more detail, the select voltage generation circuit 112 includes a ladder resistor circuit including a plurality of resistor elements connected in series. The select voltage generation circuit 112 outputs voltages obtained by dividing the power supply voltages VDDH and VSSH using the ladder resistor circuit as the select voltages VS0 to VS255. A grayscale voltage select circuit 114 selects 64 (S in a broad sense; R>S) voltages from the select voltages VS0 to VS255 in the case of using 64 grayscales based on the grayscale characteristic adjustment data set in an adjustment register 116 by the logic circuit 40, and outputs the selected voltages as grayscale voltages V0 to V63. This enables generation of a grayscale voltage having grayscale characteristics (γ-correction characteristics) optimum for the display panel. In the case of performing a polarity reversal drive, a positive ladder resistor circuit and a negative ladder resistor circuit may be provided in the select voltage generation circuit 112. The resistance value of each resistor element of the ladder resistor circuit may be changed based on the adjustment data set in the adjustment register 116. An impedance conversion circuit (voltage-follower-connected operational amplifier) may be provided in the select voltage generation circuit 112 or the grayscale voltage select circuit 114.

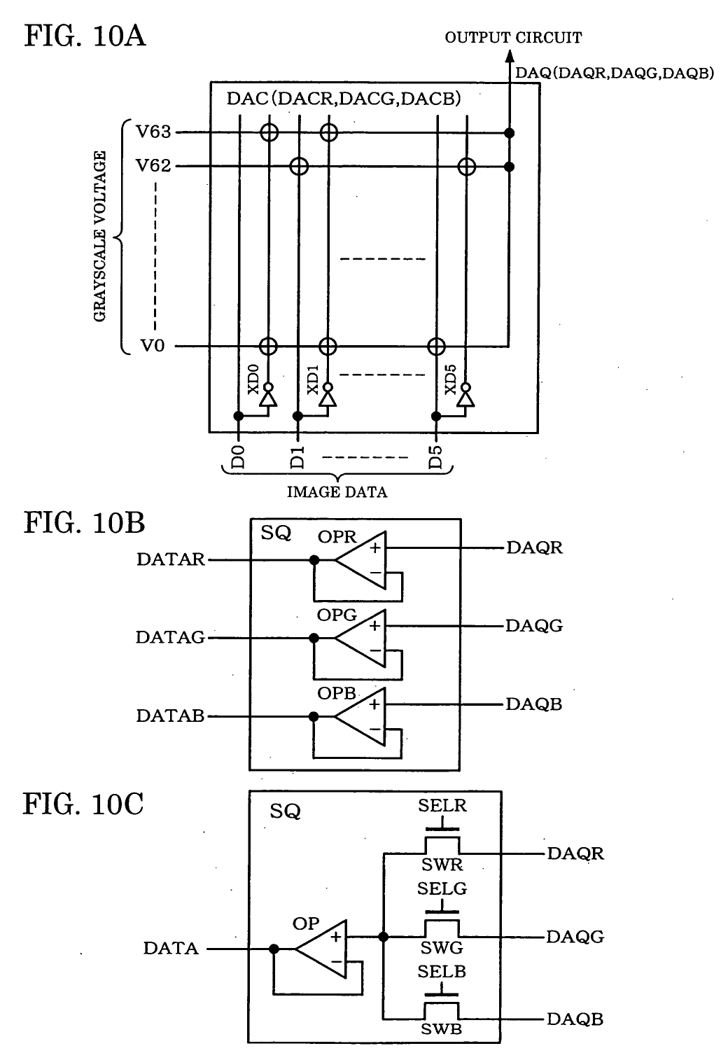

FIG. 10A shows a configuration example of a digital-analog converter (DAC) included in the D/A conversion circuit 54 shown in FIG. 8A. The DAC shown in FIG. 10A may be provided in subpixel units (or pixel units), and may be formed by a ROM decoder and the like. The DAC selects one of the grayscale voltages V0 to V63 from the grayscale voltage generation circuit 110 based on 6-bit digital image data D0 to D5 and inverted data XD0 to XD5 from the memory 20 to convert the image data D0 to D5 into analog voltages. The DAC outputs the resulting analog voltage signal DAQ (DAQR, DAQG, DAQB) to the output circuit 56.

When R, G, and B data signals are multiplexed and supplied to a low-temperature polysilicon TFT display driver or the like (FIG. 10C), R, C, and B image data may be D/A converted by using one common DAC. In this case, the DAC shown in FIG. 10A is provided in pixel units.

FIG. 10B shows a configuration example of an output section SQ included in the output circuit 56 shown in FIG. 8A. The output section SQ shown in FIG. 10B may be provided in pixel units. The output section SQ includes R (red), G (green), and B (blue) impedance conversion circuits OPR, OPG, and OPB (voltage-follower-connected operational amplifiers), performs impedance conversion of the signals DAQR, DAQG, and DAQB from the DAC, and outputs data signals DATAR, DATAC, and DATAB to R, C, and B data signal output lines. When using a low-temperature polysilicon TFT panel, switch elements (switch transistors) SWR, SWG, and SWB as shown in FIG. 10C may be provided, and the impedance conversion circuit OP may output a data signal DATA in which the R, G, and B data signals are multiplexed. The data signals may be multiplexed over a plurality of pixels. Only the switch elements and the like may be provided in the output section SQ without providing the impedance conversion circuit as shown in FIGS. 10B and 10C.

### 4. INTEGRATION INTO MACROCELL

4.1. Driver Macrocell

The integrated circuit device according to this embodiment includes at least one driver macrocell (driver macroblock) in which a plurality of circuit blocks are integrated into a macrocell (macro or macroblock), as shown in FIG. 11A. The driver macrocell is a hard macro in which routing (wiring) and circuit cell placement (arrangement) are fixed, for example. In more detail, routing and circuit cell placement of the driver macrocell are carried out by a manual layout. Note that part of routing and placement may be automated.

The driver macrocell shown in FIG. 11A includes a data driver block DB for driving data lines (source lines) and a memory block MB which stores image data. The driver macrocell also includes a pad block PDB in which pads for electrically connecting output lines of the data driver block DB with data lines of a display panel are disposed. The pad block PDB includes two rows (a plurality of rows in a broad sense) of pads disposed in a staggered arrangement in the direction D2. The pads (pad metals) are arranged in each row along the direction D1.

In FIG. 11A, the data driver block DB and the memory block MB are disposed along the direction D1, and the pad block PDB is disposed on the D2 side of the data driver block DB and the memory block MB. In more detail, the data driver block DB is adjacent to the memory block MB along the direction D1, and the data driver block DB and the memory block MB are adjacent to the pad block PDB along the direction D2. A modification is also possible in which another circuit is provided between the data driver block DB and the memory block MB, or the memory block MB is omitted from the driver macrocell.

In general, the number of pads connected with the output lines of the data driver is very large. When connecting the output lines of the data driver with the data driver pads using an automatic routing tool, the width of the integrated circuit device in the direction D2 is increased due to an increase in the area of the output line wiring region. This makes it difficult to realize a narrow chip.

In FIG. 11A, the data driver block DB and the pad block PDB are integrated into a macrocell. Therefore, a completed macrocell formed by efficiently manually routing the output lines of the data driver to the pads can be registered and used as a driver macrocell, for example. Therefore, the output line wiring region can be reduced in comparison with a method of routing the output lines of the data driver using an automatic routing tool. As a result, the width of the integrated circuit device in the direction D2 can be reduced, whereby a narrow chip can be realized.

Moreover, macrocell integration as shown in FIG. 11A allows an integrated circuit device having a layout as shown in FIGS. 5A and 5B to be realized by merely disposing the driver macrocells along the direction D1, whereby the efficiency of circuit design and layout work can be improved. For example, a change in the number of pixels of the display panel can be dealt with by merely changing the number of driver macrocells to be disposed. This makes it unnecessary to reroute the output lines of the data driver, whereby the working efficiency can be improved.

In FIG. 11A, the region on the D2 side of the memory block MB can be effectively used as the pad arrangement region in addition to the region on the D2 side of the data driver block DB. Specifically, the pads can be disposed in the region on the side of the memory block MB in the direction D2. Therefore, the pads can be efficiently disposed in the pad block PDB with a width of WPB, whereby the layout efficiency can be improved.

In the comparative example shown in FIG. 1A, since the memory block MB and the data driver block DB are disposed along the direction D2 (short side direction) corresponding to the signal flow, it is difficult to realize a narrow chip. When the memory block MB or the data driver block DB is changed in the width in the direction D2 or the length in the direction D1 due to a change in the number of pixels of the display panel, the specification of the display driver, the configuration of the memory cell, or the like, the remaining circuit blocks are affected by such a change, whereby the design efficiency is decreased.

In FIG. 1A, since the data driver block DB and the memory block MB are adjacently disposed along the direction D1, the width of the integrated circuit device in the direction D2 can be reduced. Moreover, design efficiency can be increased.

In the comparative example shown in FIG. 1A, since the wordline WL is disposed along the direction D1 (long side direction), a significant signal delay occurs in the wordline WL, whereby the read speed of image data is decreased. In particular, since the wordline WL connected with the memory cell is formed using a polysilicon layer, such a signal delay poses a serious problem.

In FIG. 11A, the wordline WL can be disposed along the direction D2 (short side direction) and the bitline BL can be disposed along the direction D1 (long side direction) in the memory block MB. In this embodiment, the integrated circuit device has a small width W in the direction D2. Therefore, the length of the wordline WL in the memory block MB can be reduced, whereby a signal delay occurring in the wordline WL can be reduced. In the comparative example shown in FIG. 1A, since the wordline WL, which is long in the direction D1 and has a large parasitic capacitance, is selected even when only the access region of the memory is accessed from the host, power consumption is increased. In FIG. 1A, since only the wordline WL provided in the memory block corresponding to the access region is selected during the host access, power consumption can be reduced.

4.2 Width of Driver Macrocell

In FIGS. 11A and 11B, when the widths of the data driver block DB, the memory block MB, and the pad block PDB in the direction D1 are respectively WDB, WMB, and WPB, the relationship “WDB+WMB≦WPB” may be satisfied.

In FIG. 1A, the width WPB of the pad block PDB in the direction D1 is almost equal to the sum of the width WDB of the data driver block DB and the width WMB of the memory block MB. Therefore, “WDB+WMB=WPB” is satisfied, for example. In FIG. 11B, a repeater block RP is disposed as an additional circuit. The repeater block RP is a circuit block including a buffer which buffers at least a write data signal (or, address signal or memory control signal) supplied to the memory block MB and outputs the write data signal to the memory block MB. In FIG. 1B, “WDB+WMB<WPB” is satisfied.

If the relationship “WDB+WMB=WPB” is satisfied, when arranging the driver macrocells along the direction D1, the pad blocks are arranged along the direction D1 without an unnecessary space being formed between the adjacent pad blocks. Therefore, the data driver pads are efficiently arranged along the direction D1, whereby the width of the integrated circuit device in the direction D1 can be reduced.

If the relationship “WDB+WMB<WPB” is satisfied, the repeater block RP (additional circuit) as shown in FIG. 11B can be disposed, whereby the layout efficiency can be increased. Specifically, when a space is formed adjacent to the memory block MB or the data driver block DB due to an increase in the width WPB of the pad block PDB resulting from the limitations to the pad pitch, an additional circuit can be disposed in the space. The additional circuit disposed in such a space is not limited to the repeater block RP. For example, part of the grayscale voltage generation circuit, a circuit which sets the output line of the data driver at a specific potential, an electrostatic protection circuit, or the like may be disposed as the additional circuit.

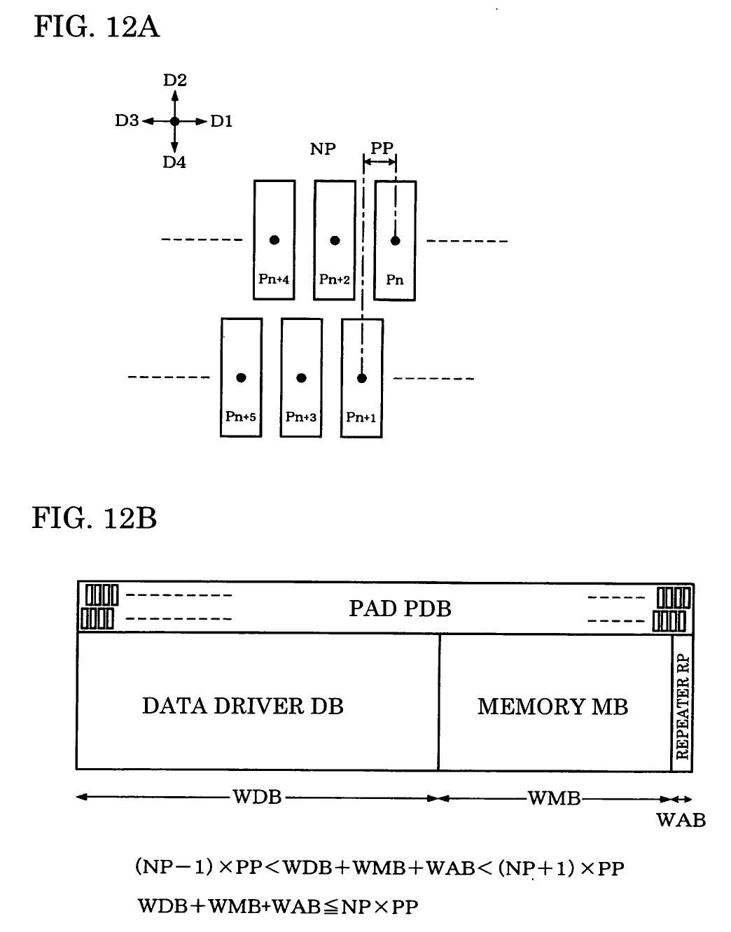

FIG. 12A shows a pad (pad metal) arrangement example in the pad block PDB. In FIG. 12A, the first row of pads arranged in the direction D1 and the second row of pads arranged in the direction D1 are stacked in the direction D2 in a staggered arrangement. Specifically, when the direction D1 is defined as the X axis and the direction D2 is defined as the Y axis, the pads are disposed so that the X coordinate of the center of the pad in the first row does not coincide with the X coordinate of the center of the pad in the second row. In FIG. 12A, the difference between the X coordinates of the centers of the pads is referred to as a pad pitch PP in the direction D1. For example, the difference between the X coordinates of the centers of the pads Pn and Pn+1 is the pad pitch PP (e.g. 20 to 22 μm).

In FIG. 12B, the width of the repeater block RP (additional circuit block) in the direction D1 is WAB, and the number of pads in the pad block PDB is NP. In this case, the relationship “(NP−1)×PP<WDB+WMB+WAB<(NP+1)×PP” is satisfied, for example.

If this relationship is satisfied, when arranging the driver macrocells along the direction D1, the pad blocks are arranged along the direction D1 so that an unnecessary space is not formed, whereby the pads can be arranged along the direction D1 at a uniform pad pitch. When the pads are arranged at a uniform pad pitch, stress uniformly occurs in the pad arrangement region when mounting the integrated circuit device on a glass substrate using bumps or the like, whereby connection failure can be prevented. When a space exists between the pads, the flow of an adhesive such as an anisotropic conductive material (e.g. ACF) may change due to the space, whereby connection failure or the like may occur. On the other hand, such a problem can be prevented by arranging the pads at a uniform pad pitch. The relationship “WDB+WMB+WAB≦NP×PP” may be satisfied. In this case, the pad pitch in the direction D1 can be made more uniform, whereby the stress can be further equalized.

When an additional circuit such as the repeater block RP is not disposed, the width WAB may be set at zero. A dummy pad (e.g. pad which is not connected with the bump or bonding wire) other than the data driver pad may be disposed in the pad block PDB. In this case, the number of pads NP may be the sum of the number of data driver pads and the number of dummy pads.

4.3 Repeater Block

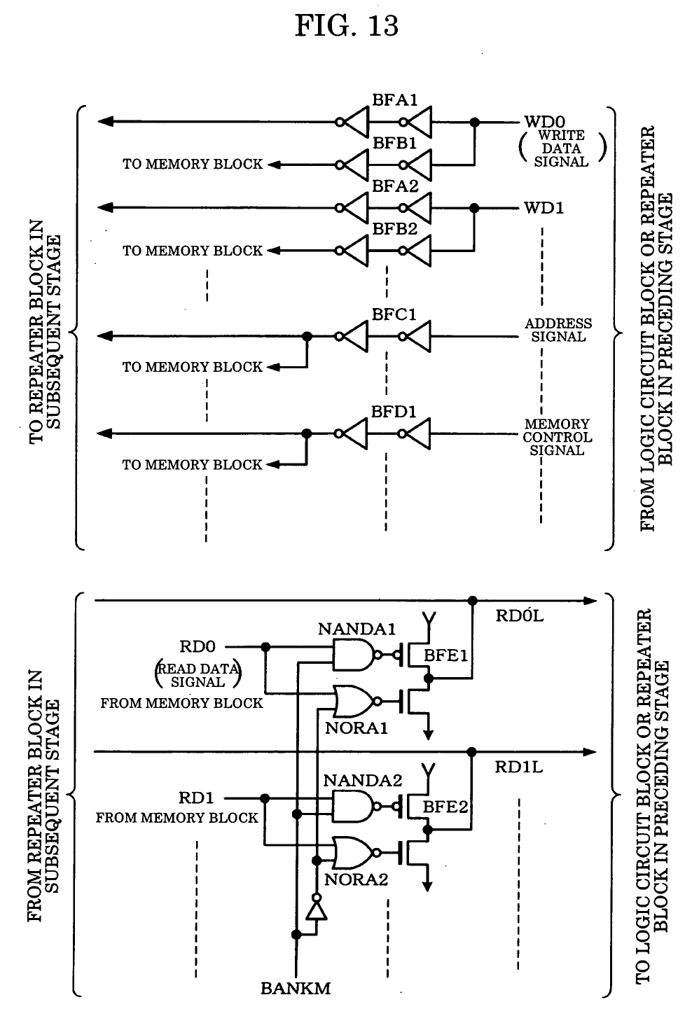

FIG. 13 shows a configuration example of the repeater block. The repeater block may be disposed adjacent to the memory block, for example. In FIG. 5B, memory global lines for transmitting the write data signal, address signal, and memory control signal from the logic circuit block LB are provided on the circuit blocks along the direction D1, and these signals are supplied from the logic circuit block LB to the memory blocks MB1 to MB4. In this case, if these signals are not buffered, the rising or falling waveform of the signals becomes round, whereby the time required to write data into the memory block may be increased, or a write error may occur.

On the other hand, when the repeater block shown in FIG. 13 is disposed adjacent to each memory block in the direction D1, for example, the write data signal, address signal, and memory control signal are buffered by the repeater block and then input to each memory block. As a result, the rising or falling waveform of the signals can be prevented from becoming round, whereby data can be appropriately written into the memory block.

In FIG. 13, the write data signals (WD0, WD1, . . . ) from the logic circuit block LB are buffered by buffers BFA1, BFA2, . . . , each of which includes two inverters, and output to the repeater block in the subsequent stage. In more detail, the buffered signals are output from the repeater block disposed on the D1 side of the memory block MB4 in FIG. 5B to the repeater block in the subsequent stage disposed on the side of the memory block MB3 in the direction D1. The write data signals from the logic circuit block LB are buffered by buffers BFB1, BFB2, . . . , and output to the memory block. In more detail, the buffered signals are output to the memory block MB4 from the repeater block disposed on the D1 side of the memory block MB4 in FIG. 5B. In this embodiment, the buffers BFA1, BFA2, . . . for outputting the write data signals to the memory block in the subsequent stage and the buffers BFB1, BFB2, . . . for outputting the write data signals to each memory block are provided. This effectively prevents a situation in which the waveform of the write data signal becomes round due to the parasitic capacitance of the memory cell of the memory block to increase the write time or cause a write error.

The address signals (e.g. CPU column address, CPU row address, and LCD row address) from the logic circuit block LB are buffered by buffers BFC1, . . . , and output to the memory block and the repeater block in the subsequent stage. The memory control signals (e.g. read/write switch signal, CPU enable signal, and bank select signal) from the logic circuit block LB are buffered by buffers BFD1, . . . , and output to the memory block and the repeater block in the subsequent stage.

The repeater block shown in FIG. 13 also includes buffers for read data signals from the memory block. In more detail, when a bank select signal BANKM has been set to active (H level) so that the memory block has been selected, the read data signals from the memory block are buffered by buffers BFE1, BFE2, . . . , and output to read data lines RD0L, RD1L, . . . . When the bank select signal BANKM has been set to inactive (L level), the outputs of the buffers BFE1, BFE2, . . . are set in a high impedance state. Therefore, the read data signals from another memory block for which the bank select signal has been set to active can be appropriately output to the logic circuit block LB.

### 5. DETAILS OF DATA DRIVER BLOCK AND MEMORY BLOCK

5.1 Block Division

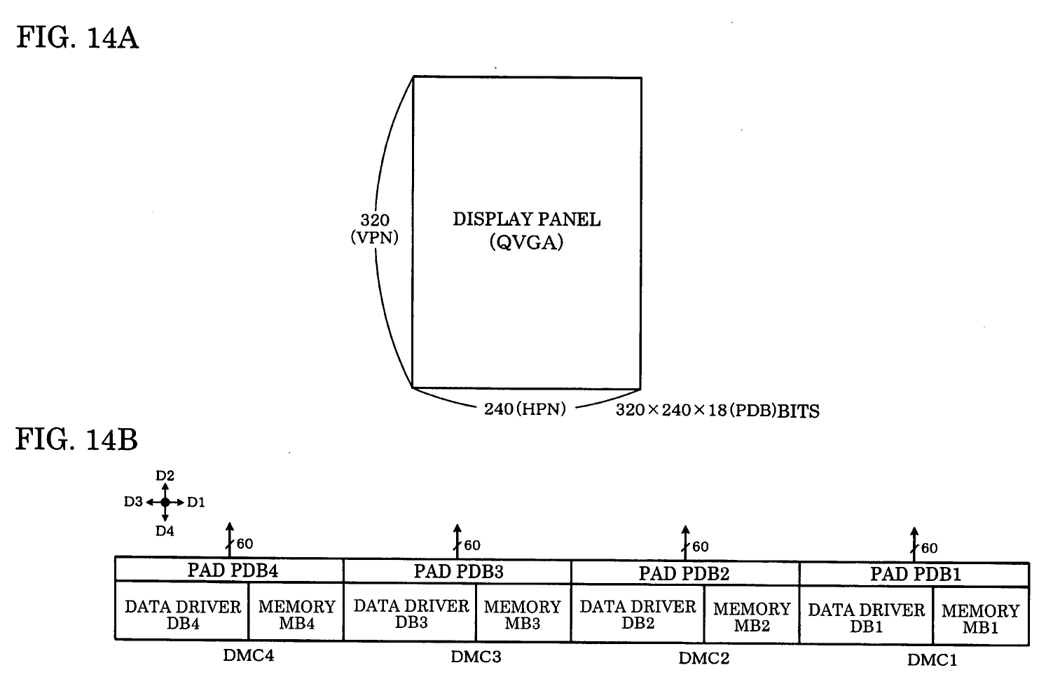

Consider the case where the display panel is a QVGA panel in which the number of pixels VPN in the vertical scan direction (data line direction) is 320 and the number of pixels HPN in the horizontal scan direction (scan line direction) is 240, as shown in FIG. 14A. Suppose that the number of bits PDB of image (display) data of one pixel is 18 bits (six bits each for R, G, and B). In this case, the number of bits of image data required to display one frame on the display panel is “VPN×HPN×PDB=320×240×18” bits. Therefore, the memory of the integrated circuit device stores at least “320×240×18” bits of image data. The data driver outputs data signals for 240 (=HPN) data lines (data signals corresponding to “240×18” bits of image data) to the display panel in units of horizontal scan periods (in units of periods in which one scan line is scanned).

In FIG. 14B, the data driver is divided into four (=DBN) data driver blocks DB1 to DB4. The memory is also divided into four (=MBN=DBN) memory blocks MB1 to MB4. Specifically, four driver macrocells DMC1, DMC2, DMC3, and DMC4, each of which includes the data driver block, the memory block, and the pad block integrated into a macrocell, are disposed along the direction D1, for example. Therefore, each of the data driver blocks DB1 to DB4 outputs data signals for 60 (=HPN/DBN= 240/4) data lines to the display panel in units of horizontal scan periods. Each of the memory blocks MB1 to MB4 stores “(VPN×HPN×PDB)/MBN=(320×240×18)/4” bits of image data.

5.2 Plurality of Read Operations in One Horizontal Scan Period

In FIG. 14B, each of the data driver blocks DB1 to DB4 outputs data signals for 60 data lines (“60×3=180” data lines when three data lines are provided for R, G, and B) in one horizontal scan period. Therefore, image data corresponding to data signals for 240 data lines must be read from the data driver blocks DB1 to DB4 corresponding to the data driver blocks DB1 to DB4 in units of horizontal scan periods.

However, when the number of bits of image data read in units of horizontal scan periods is increased, it is necessary to increase the number of memory cells (sense amplifiers) arranged in the direction D2. As a result, the width W of the integrated circuit device is increased in the direction D2 to hinder a reduction in the width of the chip. Moreover, the length of the wordline WL is increased, whereby a signal delay occurs in the wordline WL.

In this embodiment, image data stored in the memory blocks MB1 to MB4 is read from the memory blocks MB1 to MB4 into the data driver blocks DB1 to DB4 a plurality of times (RN times) in one horizontal scan period.

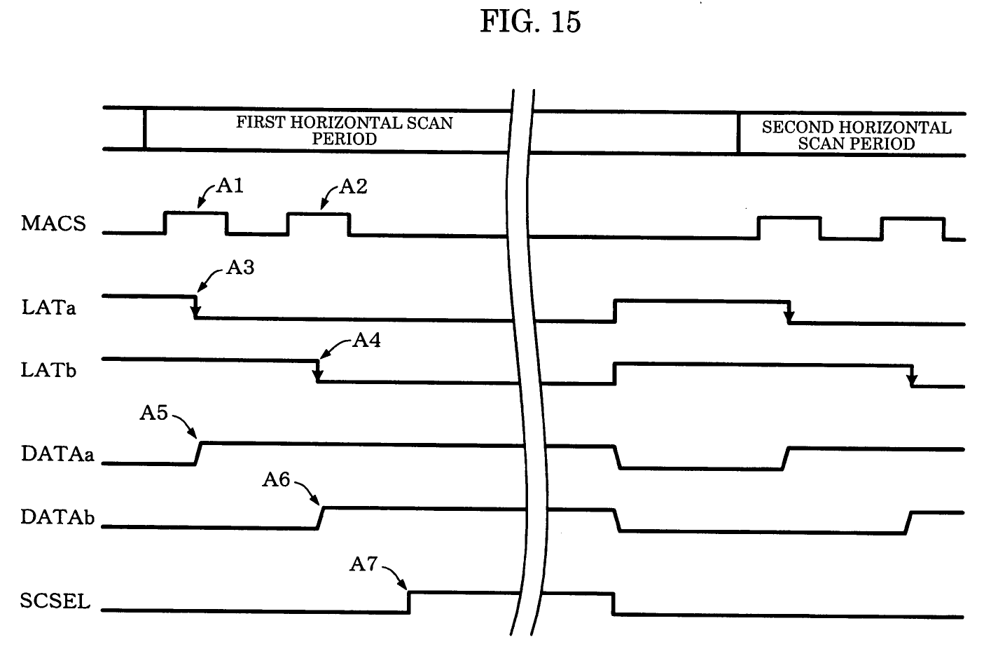

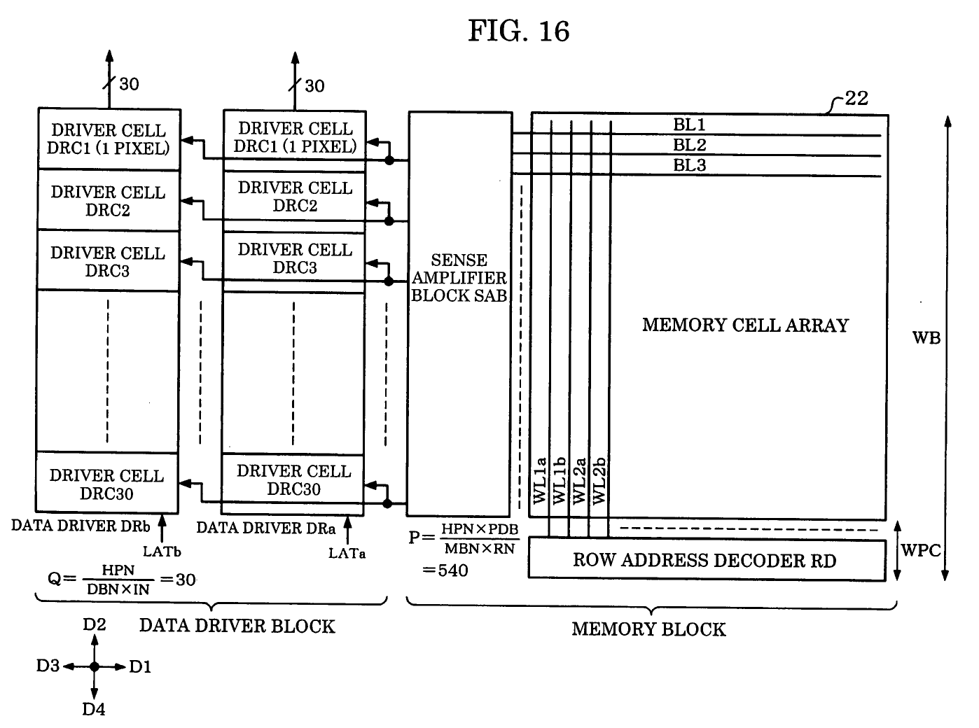

In FIG. 15, a memory access signal MACS (word select signal) goes active (high level) twice (RN=2) in one horizontal scan period, as indicated by A1 and A2, for example. This allows image data to be read from each memory block into each data driver block twice (RN=2) in one horizontal scan period. Then, data latch circuits included in data drivers DRa and DRb shown in FIG. 16 provided in the data driver block latch the image data read from the memory block based on latch signals LATa and LATb indicated by A3 and A4. D/A conversion circuits included in the data drivers DRa and DRb perform D/A conversion of the latched image data, and output circuits included in the data drivers DRa and DRb output data signals DATAa and DATAb obtained by D/A conversion to the data signal output lines, as indicated by A5 and A6. A scan signal SCSEL input to the gate of the TFT of each pixel of the display panel then goes active, as indicated by A7, and the data signal is input to and held in each pixel of the display panel.

In FIG. 15, the image data is read twice in the first horizontal scan period, and the data signals DATAa and DATAb are output to the data signal output lines in the first horizontal scan period. Note that the image data may be read twice and latched in the first horizontal scan period, and the data signals DATAa and DATAb corresponding to the latched image data may be output to the data signal output lines in the subsequent second horizontal scan period. FIG. 15 illustrates the case where the number RN of read operations is two. Note that the number RN may be three or more (RN≧3).

According to the method shown in FIG. 15, the image data corresponding to the data signals for 30 data lines is read from each memory block, and each of the data drivers DRa and DRb outputs the data signals for 30 data lines, as shown in FIG. 16. Therefore, the data signals for 60 data lines are output from each data driver block. In FIG. 15, it suffices to read the image data corresponding to the data signals for 30 data lines from each memory block in one read operation, as described above. Therefore, the number of memory cells and sense amplifiers in the direction D2 can be reduced in FIG. 16 in comparison with a method in which the image data is read only once in one horizontal scan period. As a result, the width of the integrated circuit device in the direction D2 can be reduced, whereby a very narrow chip can be realized. In a QVGA display, the length of one horizontal scan period is about 52 microseconds. On the other hand, the memory read time is about 40 nanoseconds, which is sufficiently shorter than 52 microseconds. Therefore, even if the number of read operations in one horizontal scan period is increased from one to two or more, the display characteristics are not affected to a large extent.

In addition to the QVGA (320×240) display panel shown in FIG. 14A, it is also possible to deal with a VGA (640×480) display panel by increasing the number of read operations in one horizontal scan period to four (RN=4), for example, whereby the degrees of freedom of the design can be increased.

A plurality of read operations in one horizontal scan period may be implemented using a first method in which the row address decoder (wordline select circuit) selects different wordlines in each memory block in one horizontal scan period, or a second method in which the row address decoder (wordline select circuit) selects a single wordline in each memory block a plurality of times in one horizontal scan period. Or, a plurality of read operations in one horizontal scan period may be implemented by combining the first method and the second method.

5.3 Arrangement of Data Driver and Driver Cell

FIG. 16 shows an arrangement example of data drivers and driver cells included in the data drivers. As shown in FIG. 16, the data driver block includes data drivers DRa and DRb (first to mth data drivers) arranged along the direction D1. Each of the data drivers DRa and DRb includes 30 (Q in a broad sense) driver cells DRC1 to DRC30.

When the wordline WL1a of the memory block has been selected and the first image data has been read from the memory block, as indicated by A1 in FIG. 15, the data driver DRa latches the read image data based on the latch signal LATa indicated by A3. The data driver DRa performs D/A conversion of the latched image data, and outputs the data signal DATAa corresponding to the first image data to the data signal output line, as indicated by A5.

When the wordline WL1b of the memory block has been selected and the second image data has been read from the memory block, as indicated by A2 in FIG. 15, the data driver DRb latches the read image data based on the latch signal LATb indicated by A4. The data driver DRb performs D/A conversion of the latched image data, and outputs the data signal DATAb corresponding to the second image data to the data signal output line, as indicated by A6.

Each of the data drivers DRa and DRb outputs data signals for 30 data lines corresponding to 30 pixels, whereby the data signals for 60 data lines corresponding to 60 pixels are output in total.

A problem in which the width W of the integrated circuit device in the direction D2 is increased due to an increase in the size of the data driver can be prevented by disposing (stacking) the data drivers DRa and DRb along the direction D1, as shown in FIG. 16. The data driver is configured in various ways depending on the type of display panel. In this case, data drivers having various configurations can be efficiently arranged by disposing the data drivers along the direction D1. FIG. 16 illustrates the case where the number of data drivers disposed along the direction D1 is two. Note that the number of data drivers disposed along the direction D1 may be three or more.

In FIG. 16, each of the data drivers DRa and DRb includes 30 (Q) driver cells DRC1 to DRC30 arranged along the direction D2. Each of the driver cells DRC1 to DRC30 receives image data of one pixel. Each of the driver cells DRC1 to DRCQ performs D/A conversion of the image data of one pixel, and outputs a data signal corresponding to the image data of one pixel. Each of the driver cells DRC1 to DRC30 may include a data latch circuit, the DAC (DAC for one pixel) shown in FIG. 10A, and the output section SQ shown in FIGS. 10B and 10C.

In FIG. 16, suppose that the number of pixels of the display panel in the horizontal scan direction (the number of pixels in the horizontal scan direction driven by each integrated circuit device when two or more integrated circuit devices cooperate to drive the data lines of the display panel) is HPN, the number of data driver blocks (number of block divisions) is DBN, and the number of inputs of image data to the driver cell in one horizontal scan period is IN. The number IN is equal to the number RN of image data read operations in one horizontal scan period described with reference to FIG. 15. In this case, the number Q of driver cells DRC1 to DRC30 arranged along the direction D2 may be expressed as “Q=HPN/(DBN×IN)”. In FIG. 16, since “HPN=240”, “DBN=4”, and “IN=2”, “Q=240/(4×2)=30”.

When the width (pitch) of the driver cells DRC1 to DR30 in the direction D2 is WD, and the width of the peripheral circuit section (e.g. buffer circuit and/or interconnect region) included in the data driver block in the direction D2 is WPCB, the width WB (maximum width) of the first to Nth circuit blocks CB1 to CBN in the direction D2 may be expressed as “Q×WD≦WB<(Q+1)×WD+WPC”. When the width of the peripheral circuit section (e.g. row address decoder RD and/or interconnect region) included in the memory block in the direction D2 is WPC, the width WB may be expressed as “Q×WD≦WB<(Q+1)×WD+WPC”.

Suppose that the number of pixels of the display panel in the horizontal scan direction is HPN, the number of bits of image data of one pixel is PDB, the number of memory blocks is MBN (=DBN), and the number of read operations of image data from the memory block in one horizontal scan period is RN. In this case, the number P of sense amplifiers (sense amplifiers which output one bit of image data) arranged in the sense amplifier block SAB along the direction D2 may be expressed as “P=(HPN×PDB)/(MBN×RN)”. In FIG. 16, since “HPN=240”, “PDB=18”, “MBN=4”, and “RN=2”, “P=(240×18)/(4×2)=540”. The number P is the number of effective sense amplifiers corresponding to the number of effective memory cells, and does not include the number of ineffective sense amplifiers such as a dummy memory cell sense amplifier.

When the width (pitch) of each sense amplifier included in the sense amplifier block SAB in the direction D2 is WS, the width WSAB of the sense amplifier block SAB (memory block) in the direction D2 may be expressed as “WSAB=P×WS”. When the width of the peripheral circuit section included in the memory block in the direction D2 is WPC, the width WB (maximum width) of the circuit blocks CB1 to CBN in the direction D2 may also be expressed as “P×WS≦WB<(P+PDB)×WS+WPC”.

5.4 Layout of Data Driver Block

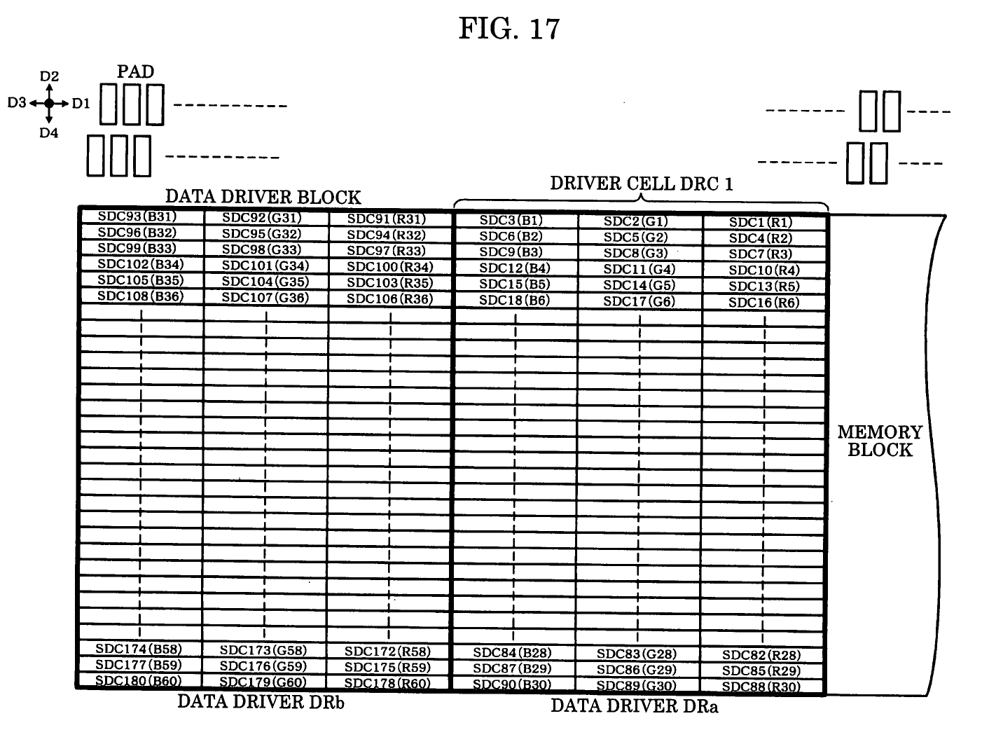

FIG. 17 shows a more detailed layout example of the data driver block. In FIG. 17, the data driver block includes a plurality of subpixel driver cells SDC1 to SDC180, each of which outputs a data signal corresponding to image data of one subpixel. In the data driver block, the subpixel driver cells are arranged along the direction D1 (direction along the long side of the subpixel driver cell) and the direction D2 perpendicular to the direction D1. Specifically, the subpixel driver cells SDC1 to SDC180 are disposed in a matrix. The pads (pad block) for electrically connecting the output lines of the data driver block with the data lines of the display panel are disposed on the D2 side of the data driver block.

For example, the driver cell DRC1 of the data driver DRa shown in FIG. 16 includes the subpixel driver cells SDC1, SDC2, and SDC3 shown in FIG. 17. The subpixel driver cells SDC1, SDC2, and SDC3 are R (red), G (green), and B (blue) subpixel driver cells, respectively. The R, G, and B image data (R1, G1, B1) corresponding to the first data signals is input to the subpixel driver cells SDC1, SDC2, and SDC3 from the memory block. The subpixel driver cells SDC1, SDC2, and SDC3 perform D/A conversion of the image data (R1, G1, B1), and output the first R, G, and B data signals (data voltages) to the R, G, and B pads corresponding to the first data lines.

Likewise, the driver cell DRC2 includes the R, G, and B subpixel driver cells SDC4, SDC5, and SDC6. The R, G, and B image data (R2, G2, B2) corresponding to the second data signals is input to the subpixel driver cells SDC4, SDC5, and SDC6 from the memory block. The subpixel driver cells SDC4, SDC5, and SDC6 perform D/A conversion of the image data (R2, G2, B2), and output the second R, G, and B data signals (data voltages) to the R, G, and B pads corresponding to the second data lines. The above description also applies to the remaining subpixel driver cells.

The number of subpixels is not limited to three, but may be four or more. The arrangement of the subpixel driver cells is not limited to the arrangement shown in FIG. 17. For example, the R, G, and B subpixel driver cells may be stacked along the direction D2.

5.5 Layout of Memory Block

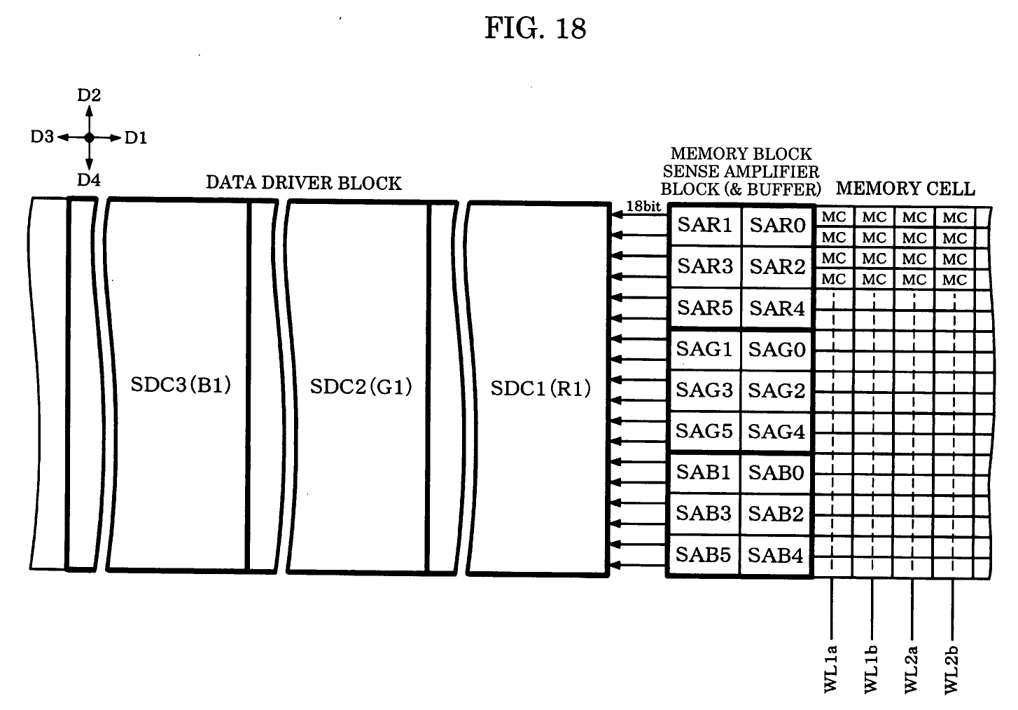

FIG. 18 shows a layout example of the memory block. FIG. 18 is a detailed view of the portion of the memory block corresponding to one pixel (six bits each for R, G, and B; 18 bits in total).

The portion of the sense amplifier block corresponding to one pixel includes R sense amplifiers SAR0 to SAR5, G sense amplifiers SAG0 to SAG5, and B sense amplifiers SAB0 to SAB5. In FIG. 18, two (a plurality of in a broad sense) sense amplifiers (and buffer) are stacked in the direction D1. Two rows of memory cells are arranged along the direction D1 on the D1 side of the stacked sense amplifiers SAR0 and SAR1, the bitline of the memory cells in the upper row being connected with the sense amplifier SAR0, and the bitline of the memory cells in the lower row being connected with the sense amplifier SAR1, for example. The sense amplifiers SAR0 and SAR1 amplify the image data signals read from the memory cells, and two bits of image data are output from the sense amplifiers SAR0 and SAR1. The above description also applies to the relationship between other sense amplifiers and memory cells.

In the configuration shown in FIG. 18, a plurality of image data read operations in one horizontal scan period shown in FIG. 15 may be realized as follows. Specifically, in the first horizontal scan period (first scan line select period), the first image data read operation is performed by selecting the wordline WL1a, and the first data signal DATAa is output as indicated by A5 in FIG. 15. In this case, R, G, and B image data from the sense amplifiers SAR0 to SAR5, SAG0 to SAG5, and SAB0 to SAB5 is respectively input to the subpixel driver cells SDC1, SDC2, and SDC3. Then, the second image data read operation is performed in the first horizontal scan period by selecting the wordline WL1b, and the second data signal DATAb is output as indicated by A6 in FIG. 15. In this case, R, G, and B image data from the sense amplifiers SAR0 to SAR5, SAG0 to SAG5, and SAB0 to SAB5 is respectively input to the subpixel driver cells SDC91, SDC92, and SDC93 shown in FIG. 17. In the subsequent second horizontal scan period (second scan line select period), the first image data read operation is performed by selecting the wordline WL2a, and the first data signal DATAa is output. Then, the second image data read operation is performed in the second horizontal scan period by selecting the wordline WL2b, and the second data signal DATAb is output.

A modification may be made in which the sense amplifiers are not stacked in the direction D1. The rows of memory cells connected with each sense amplifier may be switched using column select signals. In this case, a plurality of image data read operations in one horizontal scan period may be realized by selecting a single wordline in the memory block a plurality of times in one horizontal scan period.

5.6 Layout of Subpixel Driver Cell

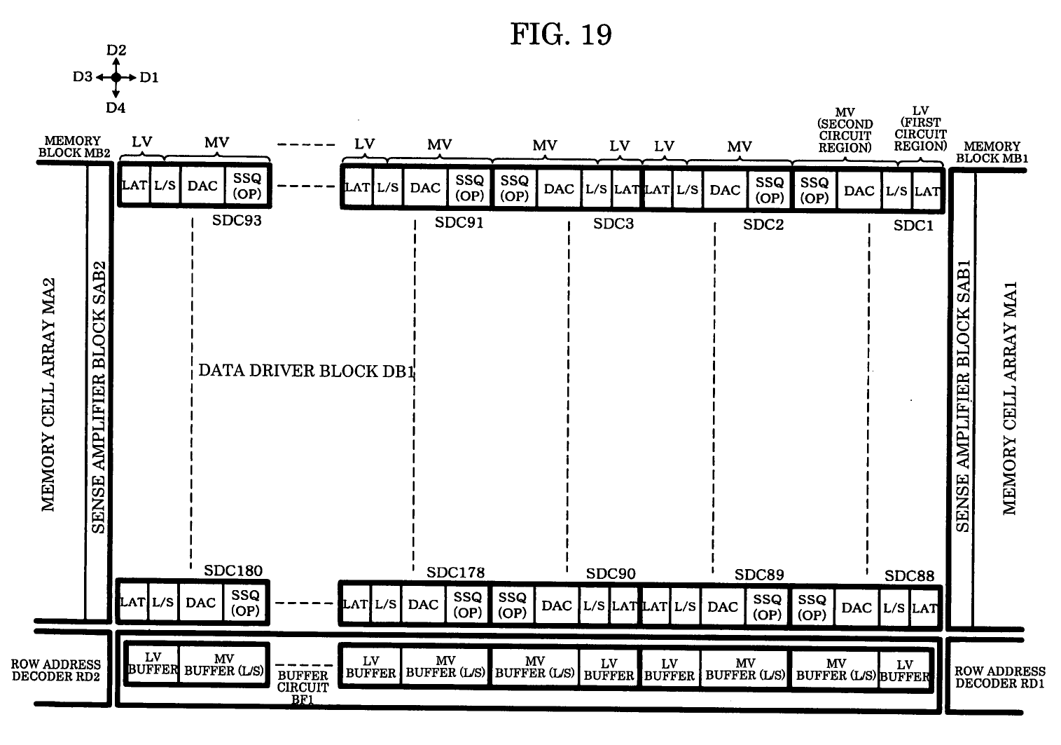

FIG. 19 shows a detailed layout example of the subpixel driver cells. As shown in FIG. 19, each of the subpixel driver cells SDC1 to SDC180 includes a latch circuit LAT, a level shifter L/S, a D/A converter DAC, and an output section SSQ. Another logic circuit such as a grayscale-control frame rate control (FRC) circuit may be provided between the latch circuit LAT and the level shifter L/S.

The latch circuit LAT included in each subpixel driver cell latches six-bit image data of one subpixel from the memory block MB1. The level shifter L/S converts the voltage level of the six-bit image data signal from the latch circuit LAT. The D/A converter DAC performs D/A conversion of the six-bit image data using the grayscale voltage. The output section SSQ includes a (voltage-follower-connected) operational amplifier OP which performs impedance conversion of the output signal from the D/A converter DAC, and drives one data line corresponding to one subpixel. The output section SSQ may include a discharge transistor (switch element), an eight-color-display transistor, and a DAC driver transistor in addition to the operational amplifier OP.

As shown in FIG. 19, each subpixel driver cell includes an LV region (first circuit region in a broad sense) in which a circuit which operates using a power supply at a low voltage (LV) level (first voltage level in a broad sense) is disposed, and an MV region (second circuit region in a broad sense) in which a circuit which operates using a power supply at a middle voltage (MV) level (second voltage level in a broad sense) higher than the LV level is disposed. The low voltage (LV) is the operating voltage of the logic circuit block LB, the memory block MB, and the like. The middle voltage (MV) is the operating voltage of the D/A converter, the operational amplifier, the power supply circuit, and the like. The output transistor of the scan driver is provided with a power supply at a high voltage (HV) level (third voltage level in a broad sense) to drive the scan line.

For example, the latch circuit LAT (or another logic circuit) is disposed in the LV region (first circuit region) of the subpixel driver cell. The D/A converter DAC and the output section SSQ including the operational amplifier OP are disposed in the MV region (second circuit region). The level shifter L/S converts the LV level signal into an MV level signal.

In FIG. 19, a buffer circuit BF1 is provided on the D4 side of the subpixel driver cells SDC1 to SDC180. The buffer circuit BF1 buffers a driver control signal from the logic circuit block LB, and outputs the driver control signal to the subpixel driver cells SDC1 to SDC180. In other words, the buffer circuit BF1 functions as a driver control signal repeater block.

In more detail, the buffer circuit BF1 includes an LV buffer disposed in the LV region and an MV buffer disposed in the MV region. The LV buffer receives and buffers the LV level driver control signal (e.g. latch signal) from the logic circuit block LB, and outputs the driver control signal to the circuit (LAT) disposed in the LV region of the subpixel driver cell on the D2 side of the LV buffer. The MV buffer receives the LV level driver control signal (e.g. DAC control signal or output control signal) from the logic circuit block LB, converts the LV level driver control signal into an MV level driver control signal using a level shifter, buffers the converted signal, and outputs the buffered signal to the circuit (DAC and SSQ) disposed in the MV region of the subpixel driver cell on the D2 side of the MV buffer.

In this embodiment, the subpixel driver cells SDC1 to SDC180 are disposed so that the MV regions (or LV regions) of the subpixel driver cells are adjacent to each other along the direction D1, as shown in FIG. 19. Specifically, the adjacent subpixel driver cells are mirror-image disposed on either side of the boundary extending along the direction D2. For example, the subpixel driver cells SDC1 and SDC2 are disposed so that the MV regions are adjacent to each other. The subpixel driver cells SDC3 and SDC91 are disposed so that the MV regions are adjacent to each other. The subpixel driver cells SDC2 and SDC3 are disposed so that the LV regions are adjacent to each other.

It is unnecessary to provide a guard ring or the like between the subpixel driver cells by disposing the subpixel driver cells so that the MV regions are adjacent to each other, as shown in FIG. 19. Therefore, the width of the data driver block in the direction D1 can be reduced in comparison with a method of disposing the subpixel driver cells so that the MV region is adjacent to the LV region, whereby the area of the integrated circuit device can be reduced.

According to the arrangement method shown in FIG. 19, the MV regions of the adjacent subpixel driver cells (driver cells) can be effectively utilized as the wiring region of pull-out lines of output signals from the subpixel driver cells, as described later, whereby the layout efficiency can be improved.

According to the arrangement method shown in FIG. 19, the memory block can be disposed adjacent to the LV region (first circuit region) of the subpixel driver cell. In FIG. 19, the memory block MB1 is disposed adjacent to the LV regions of the subpixel driver cells SDC1 and SDC88, for example. The memory block MB2 is disposed adjacent to the LV regions of the subpixel driver cells SDC93 and SDC180. The memory blocks MB1 and MB2 operate using a power supply at the LV level. Therefore, the width of the driver macrocell in the direction D1 including the data driver block and the memory block can be reduced by disposing the data driver block and the memory block so that the LV region of the subpixel driver cell is adjacent to the memory block, whereby the area of the integrated circuit device can be reduced.

According to the method shown in FIG. 19, even if the integrated circuit device does not include the memory block, the repeater block described with reference to FIG. 13 can be disposed in the region between the LV regions of the adjacent subpixel driver cells. This allows the LV level signal (image data signal) from the logic circuit block LB to be buffered by the repeater block and input to the subpixel driver cells.

5.7 D/A Converter

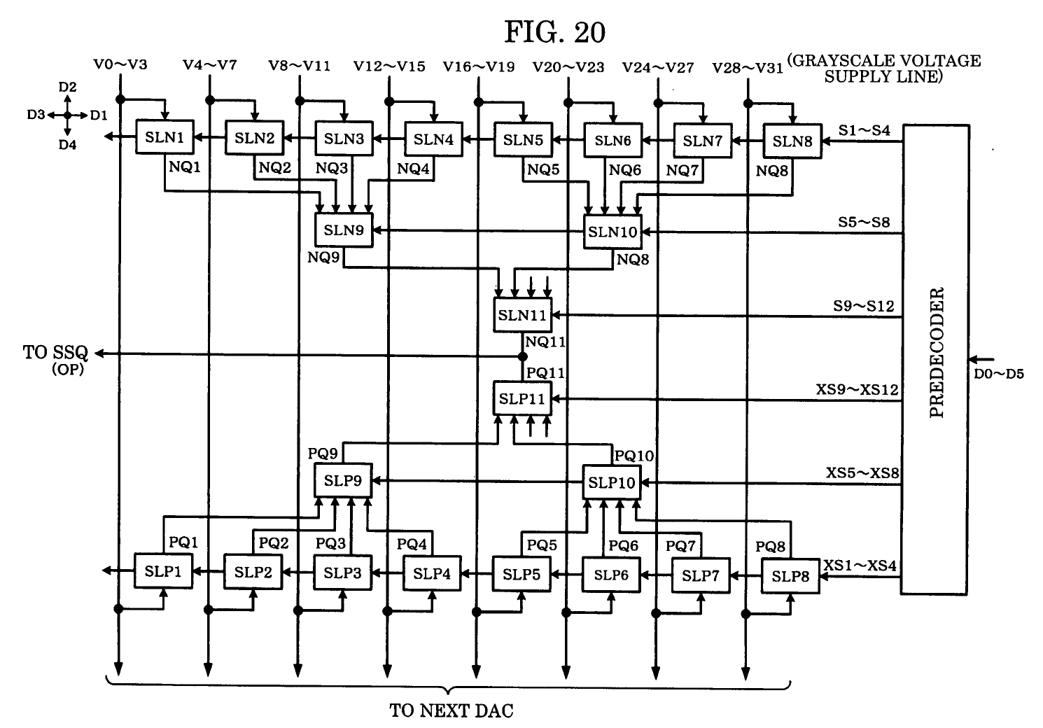

FIG. 20 shows a detailed configuration example of the D/A converter (DAC) included in the subpixel driver cell. This D/A converter is a circuit which performs tournament type D/A conversion, and includes grayscale voltage selectors SLN1 to SLN11 and SLP1 to SLP11 and a predecoder 120.

The grayscale voltage selectors SLN1 to SLN11 are selectors formed of N-type (first conductivity type in a broad sense) transistors, and the grayscale voltage selectors SLP1 to SLP11 are selectors formed of P-type (second conductivity type in a broad sense) transistors. The N-type and P-type transistors make a pair to form a transfer gate. For example, the N-type transistor which forms the grayscale voltage selector SLN1 and the P-type transistor which forms the grayscale voltage selector SLP1 make a pair to form a transfer gate.

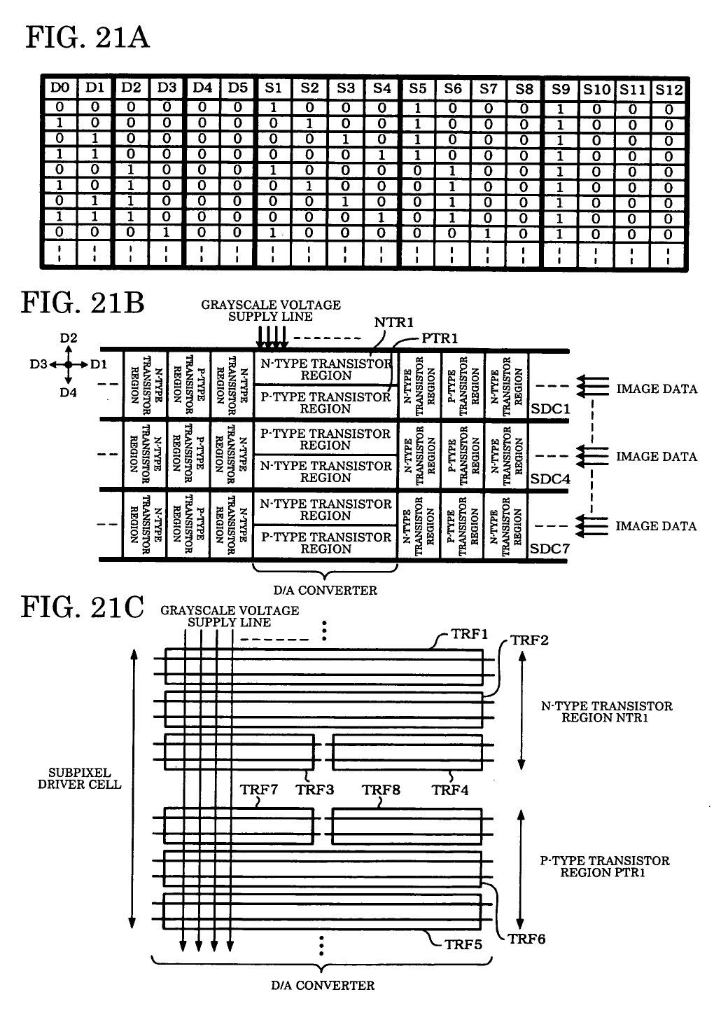

The grayscale voltage supply lines for the grayscale voltages V0 to V3, V4 to V7, V8 to V11, V12 to V15, V16 to V19, V20 to V23, V24 to V27, and V28 to V31 are respectively connected with input terminals of the grayscale voltage selectors SLN1 to SLN8 and SLP1 to SLP8. The predecoder 120 is provided with image data D0 to D5, and decodes the image data D0 to D5 as indicated by the truth table shown in FIG. 21A. The predecoder 120 outputs select signals S1 to S4 and XS1 to XS4 to the grayscale voltage selectors SLN1 to SLN8 and SLP1 to SLP9, respectively. The predecoder 120 outputs select signals S5 to S8 and XS5 to XS8 to the grayscale voltage selectors SLN9 and SLN10 and SLP9 and SLP10, respectively, and outputs select signals S9 to S12 and XS9 to XS12 to the grayscale voltage selectors SLN11 and SLP11, respectively.

For example, when the image data D0 to D5 is (100000), the select signals S2, S5, and S9 (XS2, XS5, and XS9) are set to active, as shown in the truth table in FIG. 21A. This allows the grayscale voltage selectors SLN1 and SLP1 to select the grayscale voltage V1, the grayscale voltage selectors SLN9 and SLP9 to select the outputs from the grayscale voltage selectors SLN1 and SLP1, and the grayscale voltage selectors SLN 11 and SLP 11 to select the outputs from the grayscale voltage selectors SLN9 and SLP9. Therefore, the grayscale voltage V1 is output to the output section SSQ. Likewise, when the image data D0 to D5 is (010000), since the select signal S3 (XS3) is set to active, the grayscale voltage selectors SLN1 and SLP1 select the grayscale voltage V2, and the grayscale voltage V2 is output to the output section SSQ. When the image data D0 to D5 is (001000), the select signals S1, S6, and S9 (XS1, XS6, and XS9) are set to active. Therefore, the grayscale voltage selectors SLN2 and SLP2 select the grayscale voltage V4, the grayscale voltage selectors SLN9 and SLP9 select the outputs from the grayscale voltage selectors SLN2 and SLP2, and the grayscale voltage selectors SLN11 and SLP11 select the outputs from the grayscale voltage selectors SLN9 and SLP9. Therefore, the grayscale voltage V4 is output to the output section SSQ.

In this embodiment, as shown in FIGS. 21B and 21C, the grayscale voltage supply lines for supplying the grayscale voltages V0 to V31 to the D/A converter shown in FIG. 20 are provided along the direction D2 (D4) across the subpixel driver cells. In FIG. 21B, the grayscale voltage supply lines are provided in the direction D2 across the subpixel driver cells SDC1, SDC4, and SDC7 arranged along the direction D2, for example. As shown in FIGS. 21B and 21C, the grayscale voltage supply lines are provided in the arrangement region in which the D/A converter (grayscale voltage selector) is disposed.

In more detail, as shown in FIG. 21B, an N-type transistor region (P-type well) and a P-type transistor region (N-type well) are disposed along the direction D2 in the arrangement region of the subpixel driver cell in which the D/A converter is disposed. On the other hand, an N-type transistor region (P-type well) and a P-type transistor region (N-type well) are disposed along the direction D1 perpendicular to the direction D2 in the arrangement region of a circuit (output section, level shifter, and latch circuit) of the subpixel driver cell other than the D/A converter is disposed. In other words, the subpixel driver cells adjacent along the direction D2 are mirror-image disposed on either side of the boundary extending along the direction D1. For example, the driver cells SDC1 and SDC4 are mirror-image disposed on either side of the boundary between the driver cells SDC1 and SDC4, and the driver cells SDC4 and SDC7 are mirror-image disposed on either side of the boundary between the driver cells SDC4 and SDC7.

For example, the N-type transistors forming the grayscale voltage selectors SLN1 to SLN11 of the D/A converter of the subpixel driver cell SDC1 are formed in an N-type transistor region NTR1 of the subpixel driver cell shown in FIG. 21B, and the P-type transistors forming the grayscale voltage selectors SLP1 to SLP11 are formed in a P-type transistor region PTR1. In more detail, as shown in FIG. 21C, N-type transistors TRF1 and TRF2 forming the grayscale voltage selector SLN11 and N-type transistors TRF3 and TRF4 forming the grayscale voltage selectors SLN9 and SLN10 are formed in the N-type transistor region NTR1. On the other hand, P-type transistors TRF5 and TRF6 forming the grayscale voltage selector SLP11 and P-type transistors TRF7 and TRF8 forming the grayscale voltage selectors SLP9 and SLP10 are formed in the P-type transistor region PTR1. While the N-type transistor region and the P-type transistor region of other circuits of the subpixel driver cell are disposed along the direction D1, the N-type transistor region NTR1 and the P-type transistor region PTR1 are disposed along the direction D2.

In the D/A converter shown in FIG. 20, the N-type transistor forming the grayscale voltage selector SLN1 and the P-type transistor forming the grayscale voltage selector SLP1 make a pair to form a transfer gate, for example. Therefore, the grayscale voltage supply lines can be connected in common with these P-type and N-type transistors by providing the grayscale voltage supply lines along the direction D2, whereby the transfer gate can be easily formed. Therefore, the layout efficiency can be improved.

On the other hand, it is necessary to input image data from the memory block to a circuit (e.g. latch circuit) other than the D/A converter. As shown in FIG. 21B, the image data is supplied through an image data supply line provided along the direction D1. As is clear from the layout shown in FIG. 19, the signal flow direction in the subpixel driver cell is the direction D1. Therefore, an efficient layout along the signal flow can be achieved by arranging the N-type transistor region and the P-type transistor region of the circuits other than the D/A converter along the direction D1, as shown in FIG. 21B. Therefore, the transistor region arrangement as shown in FIG. 21B is the layout optimum for the subpixel driver cells disposed as shown in FIG. 19.

5.8 Rearrangement Wiring Region

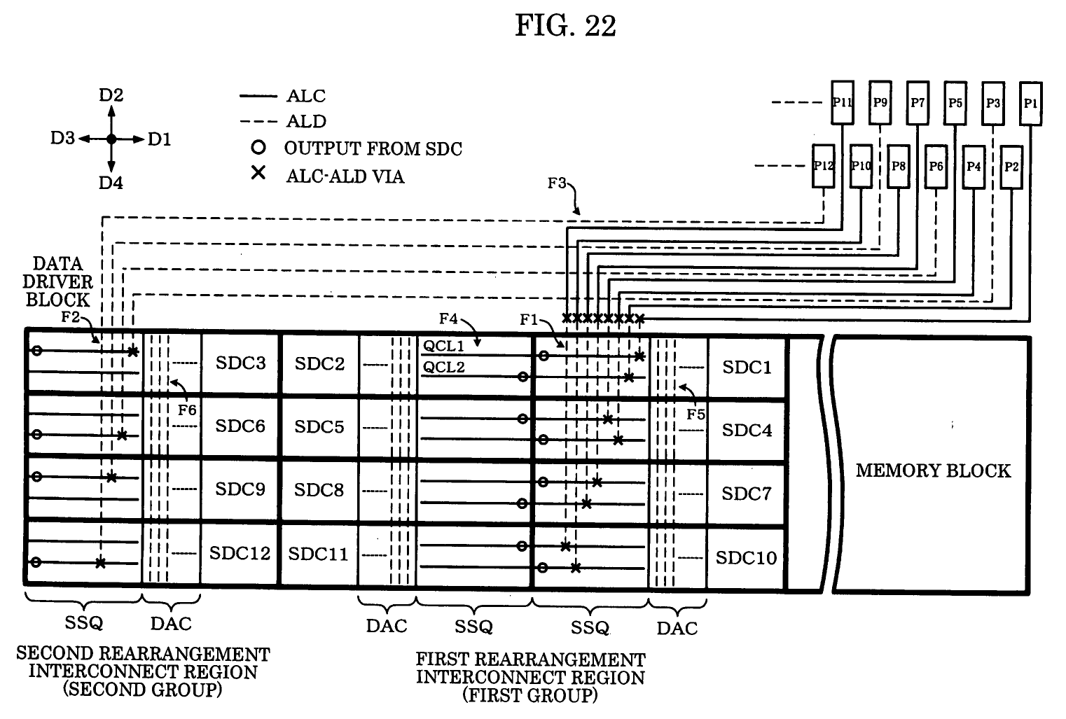

FIG. 22 is a view illustrative a pad wiring method. As indicated by F1 and F2 in FIG. 22, pull-out lines of output signals (data signals) from the subpixel driver cells are provided along the direction D2 (vertical direction). These pull-out lines are lines for outputting the output signals from the subpixel driver cells (driver cells) to the outside of the data driver block, and are formed using a fourth aluminum wiring layer ALD, for example. In FIG. 22, a rearrangement wiring region (first and second rearrangement wiring regions) for rearranging the order of the pull-out lines is provided in the arrangement region of the subpixel driver cells (driver cells). In more detail, the rearrangement wiring region is formed in a layer higher than first and second aluminum wiring layers ALA and ALB (local lines in the subpixel driver cells). In the rearrangement wiring region, the order of the pull-out lines is rearranged corresponding to the order of the pads.

Specifically, the order of the pull-out lines of the output signals from the subpixel driver cells SDC1, SDC2, SDC4, SDC5, SDC7, SDC8, . . . belonging to the first group (i.e. pull-out lines belonging to the first group indicated by F1) is rearranged in the first rearrangement wiring region. In more detail, the order of the pull-out lines is rearranged in the first rearrangement wiring region in the order of the pads P1, P2, P4, P5, P7, P8, . . . . The order of the pull-out lines of the output signals from the subpixel driver cells SDC3, SDC6, SDC9, . . . belonging to the second group (i.e. output lines belonging to the second group indicated by F2) is rearranged in the second rearrangement wiring region. In more detail, the order of the pull-out lines is rearranged in the second rearrangement wiring region in the order of the pads P3, P6, P9, . . . .

It is possible to minimize the wiring rearrangement in the region indicated by F3, which is the wiring region between the pad arrangement region and the data driver block, by providing the rearrangement wiring region in the subpixel drivers to rearrange the output lines. As a result, the width of the wiring region indicated by F3 can be reduced in the direction D2, whereby a narrow chip can be realized.

In the wiring region indicated by F3, connection lines for connecting the pull-out lines belonging to the first group indicated by F1 with the pads P1, P2, P4, P5, P7, P8, . . . are formed using the third aluminum wiring layer ALC (wiring in a given layer in a broad sense). On the other hand, connection lines for connecting the pull-out lines belonging to the second group indicated by F2 with the pads P3, P6, P9, . . . are formed using the fourth aluminum wiring layer ALD (wiring in a layer differing from the given layer in a broad sense).

In FIG. 22, an pull-out position change line for changing the pull-out position of the pull-out line is provided in the rearrangement wiring region. For example, pull-out position change lines QCL1 and QCL2 for changing the pull-out positions of the output signals from the subpixel driver cells SDC1 and SDC2 are provided, as indicated by F4. In more detail, the pull-out position change lines QCL1 and QCL2 are provided in the direction D1 (horizontal direction) across the subpixel driver cells SDC1 and SDC2 disposed along the direction D1. The pull-out position change lines QCL1 and QCL2 are formed using the third aluminum wiring layer ALC. In this case, the image data supply lines for supplying image data to the subpixel driver cells SDC1 and SC2 are also provided in the subpixel driver cells along the direction D1 using the aluminum wiring layer ALC in the same layer as the pull-out position change lines QCL1 and QCL2. The pull-out lines indicated by F1 and F2 are formed using the aluminum wiring layer ALD in a layer differing from the pull-out position change lines QCL1 and QCL2.

In FIG. 22, the grayscale voltage supply lines for supplying the grayscale voltages to the D/A converters of the subpixel driver cells are provided along the direction D2 across the subpixel driver cells, as indicated by F5 and F6. In more detail, the grayscale voltage supply lines are formed using the aluminum wiring layer ALD in the same layer as the pull-out lines.

According to the wiring method shown in FIG. 22, the pull-out position change lines, the image data supply lines, the pull-out lines, and the grayscale voltage supply lines can be efficiently formed using the aluminum wiring layers ALC and ALD, whereby the layout efficiency can be improved. Therefore, since an increase in the width of the data driver block in the directions D1 and D2 can be minimized, a narrow chip can be realized, and the area of the integrated circuit device can be reduced.

### 6. ELECTRONIC INSTRUMENT

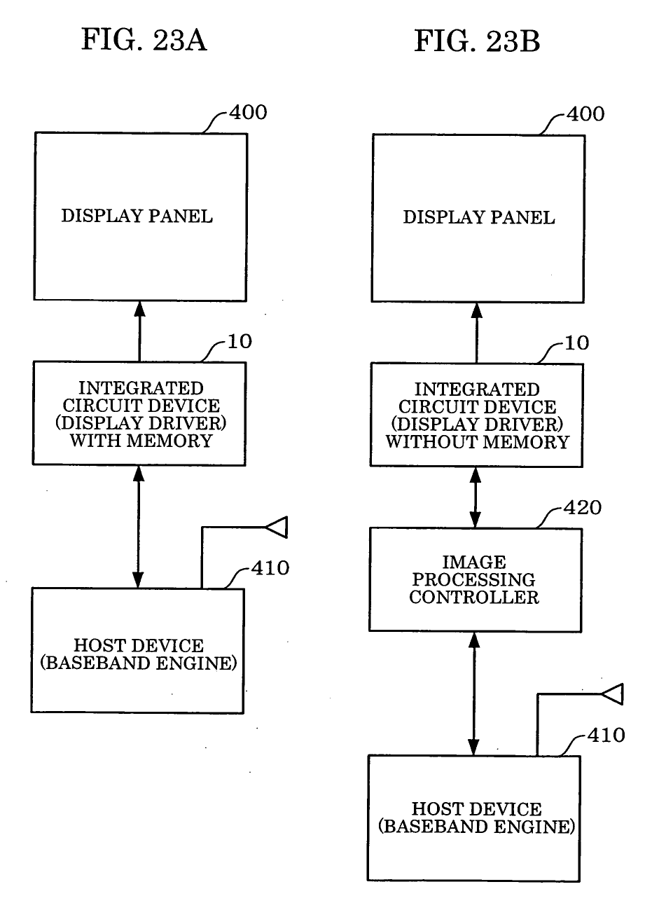

FIGS. 23A and 23B show examples of an electronic instrument (electro-optical device) including the integrated circuit device 10 according to this embodiment. The electronic instrument may include constituent elements (e.g. camera, operation section, or power supply) other than the constituent elements shown in FIGS. 23A and 23B. The electronic instrument according to this embodiment is not limited to a portable telephone, and may be a digital camera, PDA, electronic notebook, electronic dictionary, projector, rear-projection television, portable information terminal, or the like.

In FIGS. 23A and 23B, a host device 410 is a microprocessor unit (MPU), a baseband engine (baseband processor), or the like. The host device 410 controls the integrated circuit device 10 as a display driver. The host device 410 may perform processing as an application engine and a baseband engine or processing as a graphic engine such as compression, decompression, or sizing. An image processing controller (display controller) 420 shown in FIG. 23B performs processing as a graphic engine such as compression, decompression, or sizing instead of the host device 410.

A display panel 400 includes a plurality of data lines (source lines), a plurality of scan lines (gate lines), and a plurality of pixels specified by the data lines and the scan lines. A display operation is realized by changing the optical properties of an electro-optical element (liquid crystal element in a narrow sense) in each pixel region. The display panel 400 may be formed by an active matrix type panel using switch elements such as a TFT or TFD. The display panel 400 may be a panel other than an active matrix type panel, or may be a panel other than a liquid crystal panel.

In FIG. 23A, the integrated circuit device 10 may include a memory. In this case, the integrated circuit device 10 writes image data from the host device 410 into the built-in memory, and reads the written image data from the built-in memory to drive the display panel. In FIG. 23B, the integrated circuit device 10 may not include a memory. In this case, image data from the host device 410 is written into a memory provided in the image processing controller 420. The integrated circuit device 10 drives the display panel 400 under control of the image processing controller 420.

Although only some embodiments of the invention have been described in detail above, those skilled in the art will readily appreciate that many modifications are possible in the embodiments without departing from the novel teachings and advantages of this invention. Accordingly, all such modifications are intended to be included within the scope of this invention. For example, any term (such as the output-side I/F region, the input-side I/F region, the LV region and the MV region) cited with a different term having broader or the same meaning (such as the first interface region, the second interface region, the first circuit region, and the second circuit region) at least once in this specification or drawings can be replaced by the different term in any place in this specification and drawings.

The methods according to the above embodiments such as integrating the data driver block, the memory block, and the pad block into a macrocell may also be applied to an integrated circuit device having an arrangement and a configuration differing from those shown in FIG. 3. The first and second directions of the integrated circuit device need not necessarily coincide with the first and second directions of the driver macrocell and the subpixel driver cell.

What is claimed is:

1. An integrated circuit device comprising at least one driver macrocell in which a plurality of circuit blocks are integrated into a macrocell, the driver macrocell including:
a data driver block for driving data lines;
a memory block which stores image data used by the data driver block for driving the data lines; and
a pad block in which pads for electrically connecting output lines of the data driver block with the data lines are disposed,
the data driver block and the memory block being disposed along a first direction, and the pad block being disposed on a second direction side of the data driver block and the memory block, the second direction being perpendicular to the first direction.

2. The integrated circuit device as defined in claim 1, wherein, when a width of the data driver block in the first direction is WDB, a width of the memory block in the first direction is WMB, and a width of the pad block in the first direction is WPB, “WDB+WMB≦WPB” is satisfied.

3. The integrated circuit device as defined in claim 1, wherein, when a width of the data driver block in the first direction is WDB, a width of the memory block in the first direction is WMB, a width of an additional circuit block included in the driver macrocell in the first direction is WAB when the driver macrocell includes the additional circuit, a pad pitch of the pads in the pad block in the first direction is PP, and a number of the pads is NP, “(NP−1)×PP<WDB+WMB+WAB<(NP+1)×PP” is satisfied.

4. The integrated circuit device as defined in claim 3, wherein “WDB+WMB+WAB≦NP×PP” is satisfied.

5. The integrated circuit device as defined in claim 3, wherein the additional circuit block is a repeater block including a buffer which buffers at least a write data signal supplied to the memory block and outputs the buffered signal to the memory block.

6. The integrated circuit device as defined in claim 1, comprising:
a plurality of the driver macrocells;
wherein the driver macrocells are disposed along the first direction.

7. The integrated circuit device as defined in claim 1,
wherein the data driver block includes a plurality of subpixel driver cells, each of the subpixel driver cells outputting a data signal corresponding to image data of one subpixel; and
wherein the subpixel driver cells are disposed in the data driver block along the first direction and the second direction.

8. An integrated circuit device comprising at least one data driver block for driving data lines, the data driver block including:
a plurality of subpixel driver cells, each of the subpixel driver cells outputting a data signal corresponding to image data of one subpixel,
when a direction along a long side of the subpixel driver cell is a first direction and a direction perpendicular to the first direction is a second direction, the subpixel driver cells being disposed in the data driver block along the first direction and the second direction,
pads for electrically connecting output lines of the data driver block with the data lines being disposed on the second direction side of the data driver block.

9. The integrated circuit device as defined in claim 7,
wherein each of the subpixel driver cells includes:
a first circuit region in which a circuit which operates using a power supply at a first voltage level is disposed; and
a second circuit region in which a circuit which operates using a power supply at a second voltage level higher than the first voltage level is disposed; and
wherein the subpixel driver cells are disposed so that the second circuit regions or the first circuit regions of the subpixel driver cells are adjacent to each other along the first direction.

10. The integrated circuit device as defined in claim 8,
wherein each of the subpixel driver cells includes:
a first circuit region in which a circuit which operates using a power supply at a first voltage level is disposed; and
a second circuit region in which a circuit which operates using a power supply at a second voltage level higher than the first voltage level is disposed; and
wherein the subpixel driver cells are disposed so that the second circuit regions or the first circuit regions of the subpixel driver cells are adjacent to each other along the first direction.

11. The integrated circuit device as defined in claim 10,
wherein a latch circuit which latches the image data is disposed in the first circuit region; and
wherein a D/A converter which performs D/A conversion of the image data using a grayscale voltage is disposed in the second circuit region.

12. The integrated circuit device as defined in claim 9, comprising:
at least one memory block which stores the image data;
wherein the memory block is disposed adjacent to the first circuit region of the subpixel driver cell.

13. The integrated circuit device as defined in claim 10, comprising:
at least one memory block which stores the image data;
wherein the memory block is disposed adjacent to the first circuit region of the subpixel driver cell.

14. The integrated circuit device as defined in claim 7,
wherein the subpixel driver cell includes a D/A converter which performs D/A conversion of the image data using a grayscale voltage; and
wherein a grayscale voltage supply line for supplying the grayscale voltage to the D/A converter is provided along the second direction across the subpixel driver cells.

15. The integrated circuit device as defined in claim 8,
wherein the subpixel driver cell includes a D/A converter which performs D/A conversion of the image data using a grayscale voltage; and
wherein a grayscale voltage supply line for supplying the grayscale voltage to the D/A converter is provided along the second direction across the subpixel driver cells.

16. The integrated circuit device as defined in claim 15, wherein the grayscale voltage supply line is provided in an arrangement region of the D/A converter.

17. The integrated circuit device as defined in claim 14,
wherein an N-type transistor region and a P-type transistor region are disposed along the second direction in an arrangement region of the D/A converter of the subpixel driver cell; and
wherein an N-type transistor region and a P-type transistor region are disposed along the first direction in an arrangement region of a circuit of the subpixel driver cell other than the D/A converter.

18. The integrated circuit device as defined in claim 15,
wherein an N-type transistor region and a P-type transistor region are disposed along the second direction in an arrangement region of the D/A converter of the subpixel driver cell; and
wherein an N-type transistor region and a P-type transistor region are disposed along the first direction in an arrangement region of a circuit of the subpixel driver cell other than the D/A converter.

19. An electronic instrument comprising:
the integrated circuit device as defined in claim 1; and
a display panel driven by the integrated circuit device.

20. An electronic instrument comprising:
the integrated circuit device as defined in claim 8; and
a display panel driven by the integrated circuit device.
